(19) United States
(12) Patent Application Publication
(10) Pub. No.: US 2019/0267216 A1
(43) Pub. Date: Aug. 29, 2019

(54) MICROWAVE OUTPUT DEVICE AND PLASMA PROCESSING APPARATUS

(71) Applicants: Tokyo Electron Limited, Tokyo (JP); TOKYO KEIKI INC., Tokyo (JP)

(72) Inventors: Kazushi KANEKO, Kurokawa-gun, Miyagi (JP); Yuki KAWADA, Kurokawa-gun, Miyagi (JP); Kouichi MURAI, Ota-ku, Tokyo (JP); Takayuki USHIKUBO, Ota-ku, Tokyo (JP)

(73) Assignees: Tokyo Electron Limited, Tokyo (JP); TOKYO KEIKI INC., Tokyo (JP)

(21) Appl. No.: 16/342,766

(22) PCT Filed: Oct. 4, 2017
(86) PCT No.: PCT/JP2017/036137

§ 371 Date: Apr. 17, 2019

(30) Foreign Application Priority Data
Oct. 18, 2016 (JP) 2016-204390

(51) Int. Cl. H01J 37/32

(52) U.S. Cl. CPC H01J 37/32311; H01J 2237/327; H01J 37/32201

(57) ABSTRACT

In a microwave output device of an embodiment, a part of travelling wave propagating from a microwave generation unit to an output are output from a directional coupler. A first measurement unit generates an analog signal corresponding to a power of the part of the travelling wave by using diode detection, and converts the analog signal into a digital value. One or more correction coefficients associated with a set frequency and a set power of a microwave designated for the microwave output device are selected. The selected one or more correction coefficients are multiplied by the digital value, and thus a measured value is determined.

### TECHNICAL FIELD

Embodiments of the present disclosure relate to a microwave output device and a plasma processing apparatus.

### BACKGROUND ART

A plasma processing apparatus is used to manufacture an electronic device such as a semiconductor device. The plasma processing apparatus includes various types of apparatuses such as a capacitive coupling type plasma processing apparatus and an inductive coupling type plasma processing apparatus, but a plasma processing apparatus of a type of exciting a gas by using a microwave is used.

Typically, in a plasma processing apparatus, a microwave output device outputting a microwave having a single frequency is used. However, a microwave output device outputting a microwave having a bandwidth may be used, as disclosed in Patent Literature 1.

### CITATION LIST

### Patent Literature

[Patent Literature 1] Japanese Patent Application Laid-Open Publication No. 2012-109080

### SUMMARY OF INVENTION

### Technical Problem

A microwave output device includes a microwave generation unit and an output. A microwave is generated by the microwave generation unit, propagates through a waveguide path, and is then output from the output. In the plasma processing apparatus, a load is coupled to the output. Therefore, in order to stabilize a plasma generated in a chamber body of the plasma processing apparatus, a power of a microwave at the output is required to be appropriately set. To this end, it is important to measure a power of a microwave, particularly, a power of a travelling wave at the output.

In order to measure a power of a travelling wave, in the microwave output device, generally, a directional coupler is provided between the microwave generation unit and the output, and a measured value of a power of a part of a travelling wave output from the directional coupler is obtained. However, an error may occur between a power of a travelling wave at the output and a measured value of a power of a travelling wave obtained on a basis of a part of a travelling wave output from the directional coupler.

Therefore, it is necessary to reduce an error between a power of a travelling wave at the output and a measured value of a power of a travelling wave obtained on a basis of a part of a travelling wave output from the directional coupler.

### Solution to Problem

In an aspect, there is provided a microwave output device. The microwave output device includes a microwave generation unit, an output, a first directional coupler, and a first measurement unit. The microwave generation unit is configured to generate a microwave having a frequency and a power respectively corresponding to a set frequency and a set power designated from a controller. A microwave propagating from the microwave generation unit is output from the output. The first directional coupler is configured to output a part of a travelling wave propagating toward the output from the microwave generation unit. The first measurement unit is configured to determine a first measured value indicating a power of the travelling wave at the output on a basis of the part of the travelling wave output from the first directional coupler. The first measurement unit includes a first wave detection unit, a first A/D converter, and a first processing unit. The first wave detection unit is configured to generate an analog signal corresponding to a power of the part of the travelling wave by using diode detection. The first A/D converter converts the analog signal generated by the first wave detection unit into a digital value. The first processing unit is configured to select one or more first correction coefficients associated with the set frequency and the set power designated by the controller from among a plurality of first correction coefficients which are preset to correct the digital value generated by the first A/D converter to the power of the travelling wave at the output, and to determine the first measured value by multiplying the selected one or more first correction coefficients by the digital value generated by the first A/D converter.

The digital value obtained by converting by the first A/D converter an analog signal generated by the first wave detection unit has an error with respect to a power of a travelling wave at the output. The error has dependency on a set frequency and a set power of a microwave. In the microwave output device according to the aspect, a plurality of first correction coefficients are prepared in advance such that one or more first correction coefficients for reducing the error depending on a set frequency and a set power are selectable. The plurality of first correction coefficients are stored in, for example, a storage device which can be accessed by the first processing unit. In the microwave output device, one or more first correction coefficients associated with the set frequency and the set power designated from the controller are selected from among the plurality of first correction coefficients, and the first measured value is obtained by multiplying the one or more first correction coefficients by the digital value generated by the first A/D converter. Therefore, an error between a power of a travelling wave at the output and the first measured value obtained on a basis of a part of a travelling wave output from the first directional coupler is reduced.

In an embodiment, the plurality of first correction coefficients include a plurality of first coefficients respectively associated with a plurality of set frequencies and a plurality of second coefficients respectively associated with a plurality of set power levels. The first processing unit is configured to determine the first measured value by multiplying a first coefficient and a second coefficient as the one or more first correction coefficients by the digital value generated by the first A/D converter, wherein the first coefficient is one associated with the set frequency designated by the controller among the plurality of first coefficients and the second coefficient is one associated with the set power designated by the controller among the plurality of second coefficients. In the embodiment, the number of the plurality of first correction coefficients is a sum of the number of frequencies which are able to be designated as a set frequency and the number of power levels which are able to be designated as a set power. Therefore, according to the embodiment, the number of the plurality of first correction coefficients is reduced compared with a case of preparing the first correction coefficients, the number of which is a product of the number of frequencies which are able to be designated as a set frequency and the number of power levels which are able to be designated as a set power.

In an embodiment, the microwave output device further includes a second directional coupler and a second measurement unit. The second directional coupler is configured to output a part of a reflected wave returning to the output. The second measurement unit is configured to determine a second measured value indicating a power of a reflected wave at the output on a basis of the part of the reflected wave output from the second directional coupler. The second measurement unit includes a second wave detection unit, a second A/D converter, and a second processing unit. The second wave detection unit is configured to generate an analog signal corresponding to a power of the part of the reflected wave by using diode detection. The second A/D converter is configured to convert the analog signal generated by the second wave detection unit into a digital value. The second processing unit is configured to select one or more second correction coefficients associated with the set frequency and the set power designated by the controller from among a plurality of second correction coefficients which are preset to correct the digital value generated by the second A/D converter to the power of the reflected wave at the output, and to determine the second measured value by multiplying the selected one or more second correction coefficients by the digital value generated by the second A/D converter.

The digital value obtained by converting by the second A/D converter an analog signal generated by the second wave detection unit has an error with respect to a power of a reflected wave at the output. The error has dependency on a set frequency and a set power of a microwave. In the microwave output device according to the embodiment, a plurality of second correction coefficients are prepared in advance such that one or more second correction coefficients for reducing the error depending on a set frequency and a set power are selectable. The plurality of second correction coefficients are stored in, for example, a storage device which can be accessed by the second processing unit. In the microwave output device, one or more second correction coefficients associated with the set frequency and the set power designated by the controller are selected from among the plurality of second correction coefficients, and the second measured value is obtained by multiplying the one or more second correction coefficients by the digital value generated by the second A/D converter. Therefore, an error between a power of a reflected wave at the output and the second measured value obtained on a basis of a part of a reflected wave output from the second directional coupler is reduced.

In an embodiment, the plurality of second correction coefficients include a plurality of third coefficients respectively associated with a plurality of set frequencies and a plurality of fourth coefficients respectively associated with a plurality of set power levels. The second processing unit is configured to determine the second measured value by multiplying a third coefficient and a fourth coefficient as the one or more second correction coefficient by the digital value generated by the second A/D converter, wherein the third coefficient is one associated with the set frequency designated by the controller among the plurality of third coefficients and the fourth coefficient is one associated with the set power designated by the controller among the plurality of fourth coefficients. In the embodiment, the number of the plurality of second correction coefficients is a sum of the number of set frequencies and the number of set power levels. Therefore, according to the embodiment, the number of the plurality of second correction coefficients is reduced compared with a case of preparing the second correction coefficients, the number of which is a product of the number of set frequencies and the number of set power levels.

In another aspect, there is provided a microwave output device. The microwave output device includes a microwave generation unit, an output, a first directional coupler, and a first measurement unit. The microwave generation unit is configured to generate a microwave having a frequency and a power respectively corresponding to a set frequency and a set power designated from a controller. A microwave propagating from the microwave generation unit is output from the output. The first directional coupler is configured to output a part of a travelling wave propagating toward the output from the microwave generation unit. The first measurement unit is configured to determine a first measured value indicating a power of a travelling wave at the output on a basis of the part of the travelling wave from the first directional coupler. The first measurement unit includes a first spectrum analysis unit and a first processing unit. The first spectrum analysis unit is configured to obtain a digital value indicating a power of the part of the travelling wave. The first processing unit is configured to select a first correction coefficient associated with the set frequency designated by the controller from among a plurality of first correction coefficients which are preset to correct the digital value obtained by the first spectrum analysis unit to the power of the travelling wave at the output, and to determine the first measured value by multiplying the first correction coefficient by the digital value obtained by the first spectrum analysis unit.

In the microwave output device according to the aspect, the digital value obtained by the first spectrum analysis unit is multiplied by the first correction coefficient which is selected from among the plurality of first correction coefficients on a basis of the set frequency. Consequently, the first measured value is obtained. Therefore, an error between a power of a travelling wave at the output and the first measured value obtained on a basis of a part of a travelling wave output from the first directional coupler is reduced.

In an embodiment, the microwave output device further includes a second directional coupler and a second measurement unit. The second directional coupler is configured to output a part of a reflected wave returning to the output. The second measurement unit is configured to determine a second measured value indicating a power of the reflected wave at the output on a basis of the part of the reflected wave output from the second directional coupler. The second measurement unit includes a second spectrum analysis unit and a second processing unit. The second spectrum analysis unit is configured to obtain a digital value indicating a power of the part of the reflected wave. The second processing unit is configured to select a second correction coefficient associated with the set frequency designated by the controller from among a plurality of second correction coefficients which are preset to correct the digital value obtained by the second spectrum analysis unit to the power of the reflected wave at the output, and to determine the second measured value by multiplying the selected second correction coefficient by the digital value obtained by the second spectrum analysis unit.

In the microwave output device according to the embodiment, the digital value obtained by the second spectrum analysis unit through spectrum analysis is multiplied by a second correction coefficient which is selected from among a plurality of second correction coefficients on a basis of the set frequency. Consequently, the second measured value is obtained. Therefore, an error between a power of a reflected wave at the output and the second measured value obtained on a basis of a part of a reflected wave output from the second directional coupler is reduced.

In an embodiment, the microwave generation unit includes a power control unit that adjusts a power of the microwave generated by the microwave generation unit to make a difference between the first measured value and the second measured value closer to the set power designated by the controller. In the embodiment, a load power of a microwave supplied to a load coupled to the output of the microwave output device can be made closer to the set power.

In still another aspect, there is provided a plasma processing apparatus. The plasma processing apparatus includes a chamber body and the microwave output device. The microwave output device is configured to output a microwave for exciting a gas to be supplied to the chamber body. The microwave output device is the microwave output device according to any one of the plurality of aspects and the plurality of embodiments.

### Advantageous Effects of Invention

As described above, it is possible to reduce an error between a power of a travelling wave at the output and a measured value of a power of a travelling wave obtained on a basis of a part of a travelling wave output from a directional coupler.

### BRIEF DESCRIPTION OF DRAWINGS

FIG. 1 is a diagram illustrating a plasma processing apparatus according to an embodiment.

FIG. 2 is a diagram illustrating a microwave output device of a first example.

FIG. 3 is a diagram illustrating a microwave output device of a second example.

FIG. 4 is a diagram illustrating a microwave output device of a third example.

FIG. 5 is a diagram illustrating a first measurement unit of a first example.

FIG. 6 is a diagram illustrating a second measurement unit of a first example.

FIG. 7 is a diagram illustrating a configuration of a system including a microwave output device in a case where a plurality of first correction coefficients are prepared.

FIG. 8 is a flowchart illustrating a method of preparing a plurality of first correction coefficients k_{f}(F,P).

FIG. 9 is a diagram illustrating a configuration of a system including a microwave output device in a case where a plurality of second correction coefficients are prepared.

FIG. 10 is a flowchart illustrating a method of preparing a plurality of second correction coefficients kᵣ(F,P).

FIG. 11 is a flowchart illustrating a method of preparing a plurality of first coefficients k1_{f}(F) and a plurality of second coefficients k2_{f}(P) as the plurality of first correction coefficients.

FIG. 12 is a flowchart illustrating a method of preparing a plurality of third coefficients k1ᵣ(F) and a plurality of fourth coefficients k2ᵣ(P) as the plurality of second correction coefficients.

FIG. 13 is a diagram illustrating a first measurement unit of a second example.

FIG. 14 is a diagram illustrating a second measurement unit of a second example.

FIG. 15 is a flowchart illustrating a method of preparing a plurality of first correction coefficients kₛₜ(F).

FIG. 16 is a flowchart illustrating a method of preparing a plurality of second correction coefficients kₛᵣ(F).

### DESCRIPTION OF EMBODIMENTS

Hereinafter, various embodiments will be described in detail with reference to the drawings. In the drawings, the same or equivalent portions are denoted by the same reference symbols.

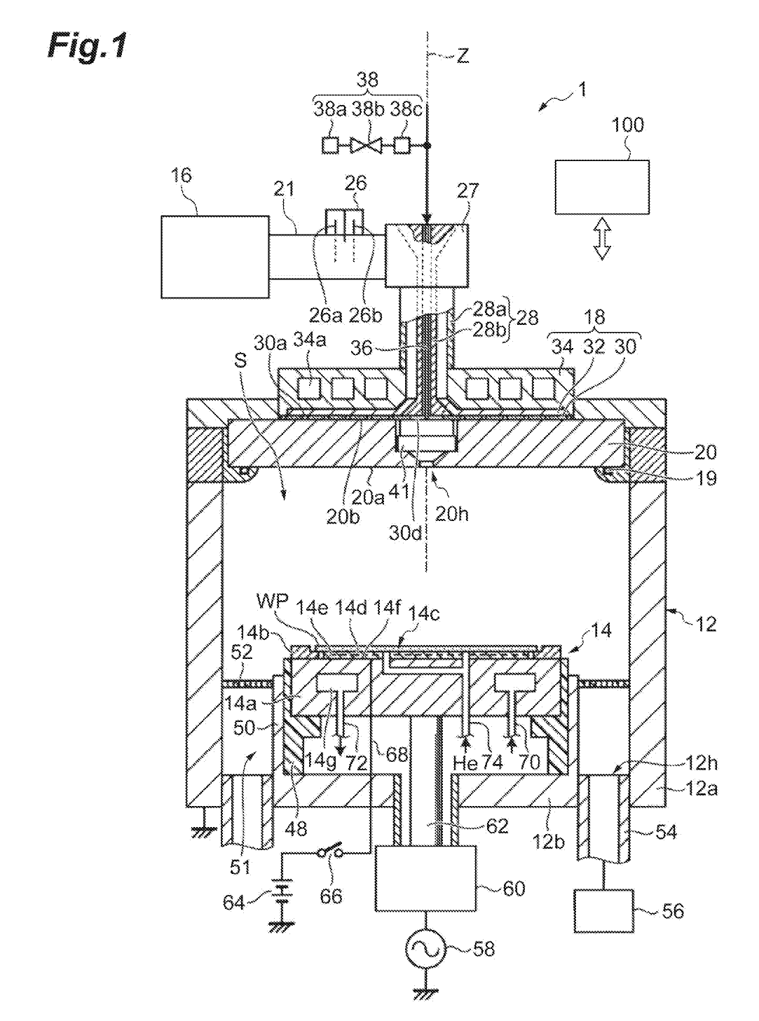

FIG. 1 is a view illustrating a plasma processing apparatus according to an embodiment. As illustrated in FIG. 1, a plasma processing apparatus 1 includes a chamber body 12 and a microwave output device 16. The plasma processing apparatus 1 may further include a stage 14, an antenna 18, and a dielectric window 20.

The chamber body 12 provides a processing space S at the inside thereof. The chamber body 12 includes a side wall 12a and a bottom portion 12b. The side wall 12a is formed in a substantially cylindrical shape. A central axis of the side wall 12a substantially coincides with an axis Z which extends in a vertical direction. The bottom portion 12b is provided on a lower end side of the side wall 12a. An exhaust hole 12h for exhaust is provided in the bottom portion 12b. An upper end of the side wall 12a provides an opening.

The dielectric window 20 is provided on the upper end of the side wall 12a. The dielectric window 20 includes a lower surface 20a which faces the processing space S. The dielectric window 20 closes the opening in the upper end of the side wall 12a. An O-ring 19 is interposed between the dielectric window 20 and the upper end of the side wall 12a. The chamber body 12 is more reliably sealed due to the O-ring 19.

The stage 14 is accommodated in the processing space S. The stage 14 is provided to face the dielectric window 20 in the vertical direction. The stage 14 is provided such that the processing space S is provided between the dielectric window 20 and the stage 14. The stage 14 is configured to support a workpiece WP (for example, a wafer) which is mounted thereon.

In an embodiment, the stage 14 includes a base 14a and an electrostatic chuck 14c. The base 14a has a substantially disc shape, and is formed from a conductive material such as aluminum. A central axis of the base 14a substantially coincides with the axis Z. The base 14a is supported by a cylindrical support 48. The cylindrical support 48 is formed from an insulating material, and extends from the bottom portion 12b in a vertically upward direction. A conductive cylindrical support 50 is provided along an outer circumference of the cylindrical support 48. The cylindrical support 50 extends from the bottom portion 12b of the chamber body 12 along the outer circumference of the cylindrical support 48 in a vertically upward direction. An annular exhaust path 51 is formed between the cylindrical support 50 and the side wall 12a.

A baffle plate 52 is provided at an upper portion of the exhaust path 51. The baffle plate 52 has an annular shape. A plurality of through-holes, which pass through the baffle plate 52 in a plate thickness direction, are formed in the baffle plate 52. The above-described exhaust hole 12h is provided on a lower side of the baffle plate 52. An exhaust device 56 is connected to the exhaust hole 12h through an exhaust pipe 54. The exhaust device 56 includes an automatic pressure control valve (APC), and a vacuum pump such as a turbo-molecular pump. A pressure inside the processing space S may be reduced to a desired vacuum degree by the exhaust device 56.

The base 14a also functions as a radio frequency electrode. A radio frequency power supply 58 for a radio frequency bias is electrically connected to the base 14a through a feeding rod 62 and a matching unit 60. The radio frequency power supply 58 outputs a radio frequency wave (hereinafter, referred to as a “bias radio frequency wave” as appropriate) having a constant frequency which is suitable to control ion energy attracted to the workpiece WP, for example, a radio frequency of 13.65 MHz with a power which is set. The matching unit 60 accommodates a matching device configured to attain matching between impedance on the radio frequency power supply 58 side, and impedance mainly on a load side such as an electrode, plasma, and the chamber body 12. A blocking capacitor for self-bias generation is included in the matching device.

The electrostatic chuck 14c is provided on an upper surface of the base 14a. The electrostatic chuck 14c holds the workpiece WP with an electrostatic attraction force. The electrostatic chuck 14c includes an electrode 14d, an insulating film 14e, and an insulating film 14f, and has a substantially disc shape. A central axis of the electrostatic chuck 14c substantially coincides with the axis Z. The electrode 14d of the electrostatic chuck 14c is formed with a conductive film, and is provided between the insulating film 14e and the insulating film 14f. A DC power supply 64 is electrically connected to the electrode 14d through a switch 66 and a covered wire 68. The electrostatic chuck 14c can attract the workpiece WP to the electrostatic chuck 14c and hold the workpiece WP by a coulomb's force which is generated by a DC voltage applied from the DC power supply 64. A focus ring 14b is provided on the base 14a. The focus ring 14b is disposed to surround the workpiece WP and the electrostatic chuck 14c.

A coolant chamber 14g is provided at the inside of the base 14a. For example, the coolant chamber 14g is formed to extend around the axis Z. A coolant is supplied into the coolant chamber 14g from a chiller unit through a pipe 70. The coolant, which is supplied into the coolant chamber 14g, returns to the chiller unit through a pipe 72. A temperature of the coolant is controlled by the chiller unit, and thus a temperature of the electrostatic chuck 14c and a temperature of the workpiece WP are controlled.

A gas supply line 74 is formed in the stage 14. The gas supply line 74 is provided to supply a heat transfer gas, for example, a He gas to a space between an upper surface of the electrostatic chuck 14c and a rear surface of the workpiece WP.

The microwave output device 16 outputs a microwave having a single frequency, that is, a single peak (SP) for exciting a process gas which is supplied into the chamber body 12. The microwave output device 16 is configured to variably adjust a frequency and a power of the microwave. In one example, the microwave output device 16 may adjust the power of the microwave in a range of 0 W to 5000 W, and may adjust the frequency of the microwave in a range of 2400 MHz to 2500 MHz.

The plasma processing apparatus 1 further includes a waveguide 21, a tuner 26, a mode converter 27, and a coaxial waveguide 28. An output of the microwave output device 16 is connected to one end of the waveguide 21. The other end of the waveguide 21 is connected to the mode converter 27. For example, the waveguide 21 is a rectangular waveguide. The tuner 26 is provided in the waveguide 21. The tuner 26 has movable plates 26a and 26b. Each of the movable plates 26a and 26b is configured to adjust a protrusion amount thereof with respect to an inner space of the waveguide 21. The tuner 26 adjusts a protrusion position of each of the movable plates 26a and 26b with respect to a reference position so as to match impedance of the microwave output device 16 with impedance of a load, for example, impedance of the chamber body 12.

The mode converter 27 converts a mode of the microwave transmitted from the waveguide 21, and supplies the microwave having undergone mode conversion to the coaxial waveguide 28. The coaxial waveguide 28 includes an outer conductor 28a and an inner conductor 28b. The outer conductor 28a has a substantially cylindrical shape, and a central axis thereof substantially coincides with the axis Z. The inner conductor 28b has a substantially cylindrical shape, and extends on an inner side of the outer conductor 28a. A central axis of the inner conductor 28b substantially coincides with the axis Z. The coaxial waveguide 28 transmits the microwave from the mode converter 27 to the antenna 18.

The antenna 18 is provided on a surface 20b opposite to the lower surface 20a of the dielectric window 20. The antenna 18 includes a slot plate 30, a dielectric plate 32, and a cooling jacket 34.

The slot plate 30 is provided on a surface 20b of the dielectric window 20. The slot plate 30 is formed from a conductive metal, and has a substantially disc shape. A central axis of the slot plate 30 substantially coincides with the axis Z. A plurality of slot holes 30a are formed in the slot plate 30. In one example, the plurality of slot holes 30a constitute a plurality of slot pairs. Each of the plurality of slot pairs includes two slot holes 30a which extend in directions interesting each other and have a substantially elongated hole shape. The plurality of slot pairs are arranged along one or more concentric circles centering around the axis Z. A through-hole 30d, through which a conduit 36 to be described later can pass, is formed in the central portion of the slot plate 30.

The dielectric plate 32 is formed on the slot plate 30. The dielectric plate 32 is formed from a dielectric material such as quartz, and has a substantially disc shape. A central axis of the dielectric plate 32 substantially coincides with the axis Z. The cooling jacket 34 is provided on the dielectric plate 32. The dielectric plate 32 is provided between the cooling jacket 34 and the slot plate 30.

A surface of the cooling jacket 34 has conductivity. A flow passage 34a is formed at the inside of the cooling jacket 34. A coolant is supplied to the flow passage 34a. A lower end of the outer conductor 28a is electrically connected to an upper surface of the cooling jacket 34. A lower end of the inner conductor 28b passes through a hole formed in a central portion of the cooling jacket 34 and the dielectric plate 32 and is electrically connected to the slot plate 30.

A microwave from the coaxial waveguide 28 propagates through the inside of the dielectric plate 32 and is supplied to the dielectric window 20 from the plurality of slot holes 30a of the slot plate 30. The microwave, which is supplied to the dielectric window 20, is introduced into the processing space S.

The conduit 36 passes through an inner hole of the inner conductor 28b of the coaxial waveguide 28. As described above, the through-hole 30d, through which the conduit 36 can pass, is formed at the central portion of the slot plate 30. The conduit 36 extends to pass through the inner hole of the inner conductor 28b, and is connected to a gas supply system 38.

The gas supply system 38 supplies a process gas for processing the workpiece WP to the conduit 36. The gas supply system 38 may include a gas source 38a, a valve 38b, and a flow rate controller 38c. The gas source 38a is a gas source of the process gas. The valve 38b switches supply and supply stoppage of the process gas from the gas source 38a. For example, the flow rate controller 38c is a mass flow controller, and adjusts a flow rate of the process gas from the gas source 38a.

The plasma processing apparatus 1 may further include an injector 41. The injector 41 supplies a gas from the conduit 36 to a through-hole 20h which is formed in the dielectric window 20. The gas, which is supplied to the through-hole 20h of the dielectric window 20, is supplied to the processing space S. The process gas is excited by a microwave which is introduced into the processing space S from the dielectric window 20. Accordingly, a plasma is generated in the processing space S, and the workpiece WP is processed by active species such as ions and/or radicals from the plasma.

The plasma processing apparatus 1 further includes a controller 100. The controller 100 collectively controls respective units of the plasma processing apparatus 1. The controller 100 may include a processor such as a CPU, a user interface, and a storage unit.

The processor executes a program and a process recipe which are stored in the storage unit to collectively control respective units such as the microwave output device 16, the stage 14, the gas supply system 38, and the exhaust device 56.

The user interface includes a keyboard or a touch panel with which a process manager performs a command input operation and the like so as to manage the plasma processing apparatus 1, a display which visually displays an operation situation of the plasma processing apparatus 1 and the like.

The storage unit stores control programs (software) for realizing various kinds of processing executed by the plasma processing apparatus 1 by a control of the processor, a process recipe including process condition data and the like, and the like. The processor calls various kinds of control programs from the storage unit and executes the control programs in correspondence with necessity including an instruction from the user interface. Desired processing is executed in the plasma processing apparatus 1 under the control of the processor.

[Configuration Examples of Microwave Output Device 16]

Hereinafter, details of three examples of the microwave output device 16 will be described.

[First Example of Microwave Output Device 16]

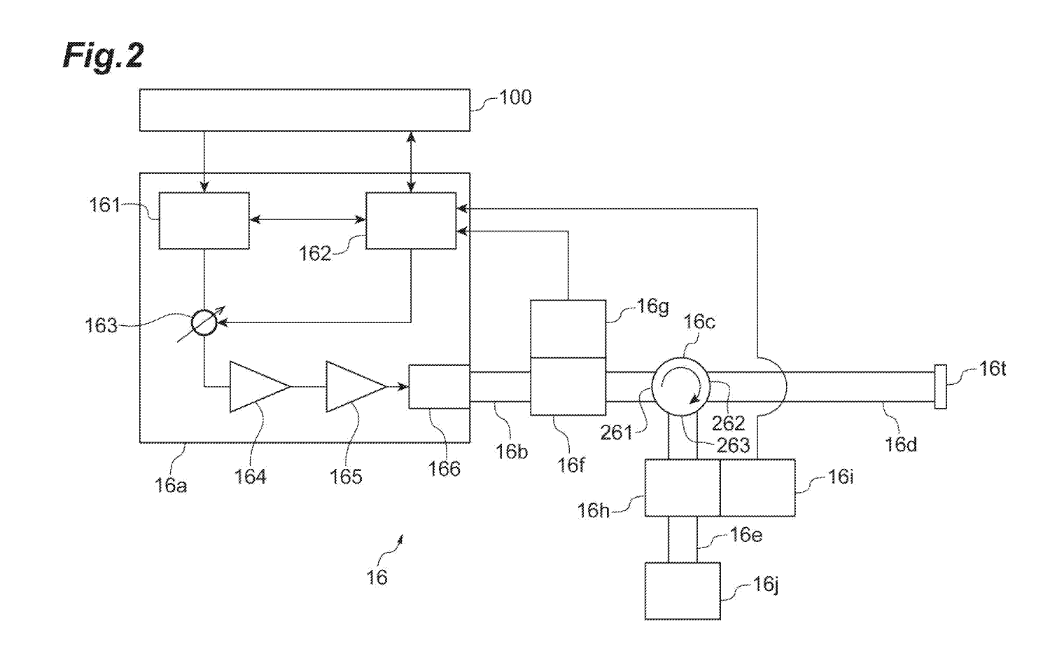

FIG. 2 is a diagram illustrating a microwave output device of a first example. The microwave output device 16 includes a microwave generation unit 16a, a waveguide 16b, a circulator 16c, a waveguide 16d, a waveguide 16e, a first directional coupler 16f, a first measurement unit 16g, a second directional coupler 16h, a second measurement unit 16i, and a dummy load 16j.

The microwave generation unit 16a includes a waveform generation unit 161, a power control unit 162, an attenuator 163, an amplifier 164, an amplifier 165, and a mode converter 166. The waveform generation unit 161 generates a microwave. The waveform generation unit 161 is connected to the controller 100 and the power control unit 162. The waveform generation unit 161 generates a single-peak microwave having a frequency corresponding to a set frequency designated by the controller 100. The waveform generation unit 161 has, for example, a phase locked loop (PLL) oscillator which generates a single-peak microwave having a frequency corresponding to the set frequency.

An output of the waveform generation unit 161 is connected to the attenuator 163. The attenuator 163 is connected to the power control unit 162. The power control unit 162 may be, for example, a processor. The power control unit 162 controls an attenuation rate of a microwave in the attenuator 163 such that a microwave having a power corresponding to a set power designated by the controller 100 is output from the microwave output device 16. An output of the attenuator 163 is connected to the mode converter 166 via the amplifier 164 and the amplifier 165. Each of the amplifier 164 and the amplifier 165 amplifies a microwave at a predetermined amplification rate. The mode converter 166 converts a mode of a microwave output from the amplifier 165. A microwave, which is generated through the mode conversion in the mode converter 166, is output as an output microwave of the microwave generation unit 16a.

An output of the microwave generation unit 16a is connected to one end of the waveguide 16b. The other end of the waveguide 16b is connected to a first port 261 of the circulator 16c. The circulator 16c includes the first port 261, a second port 262, and a third port 263. The circulator 16c outputs a microwave, which is input to the first port 261, from the second port 262, and outputs a microwave, which is input to the second port 262, from the third port 263. One end of the waveguide 16d is connected to the second port 262 of the circulator 16c. The other end of the waveguide 16d is an output 16t of the microwave output device 16.

One end of the waveguide 16e is connected to the third port 263 of the circulator 16c. The other end of the waveguide 16e is connected to the dummy load 16j. The dummy load 16j receives a microwave which propagates through the waveguide 16e and absorbs the microwave. For example, the dummy load 16j converts the microwave into heat.

The first directional coupler 16f is configured to branch a part of a microwave (that is, a travelling wave) which is output from the microwave generation unit 16a and propagates to the output 16t, and to output the part of the travelling wave. The first measurement unit 16g determines a first measured value indicating a power of a travelling wave at the output 16t on a basis of the part of the travelling wave output from the first directional coupler 16f.

The second directional coupler 16h is configured to branch a part of a microwave (that is, a reflected wave) which returns to the output 16t, and to output the part of the reflected wave. The second measurement unit 16i determines a second measured value indicating a power of a reflected wave at the output 16t on a basis of the part of the reflected wave output from the second directional coupler 16h.

The first measurement unit 16g and the second measurement unit 16i are connected to the power control unit 162. The first measurement unit 16g outputs the first measured value to the power control unit 162, and the second measurement unit 16i outputs the second measured value to the power control unit 162. The power control unit 162 controls the attenuator 163 so that a difference between the first measured value and the second measured value, that is, a load power coincides with the set power designated by the controller 100, and controls the waveform generation unit 161 as necessary.

In the first example, the first directional coupler 16f is provided between one end and the other end of the waveguide 16b. The second directional coupler 16h is provided between one end and the other end of the waveguide 16e.

[Second Example of Microwave Output Device 16]

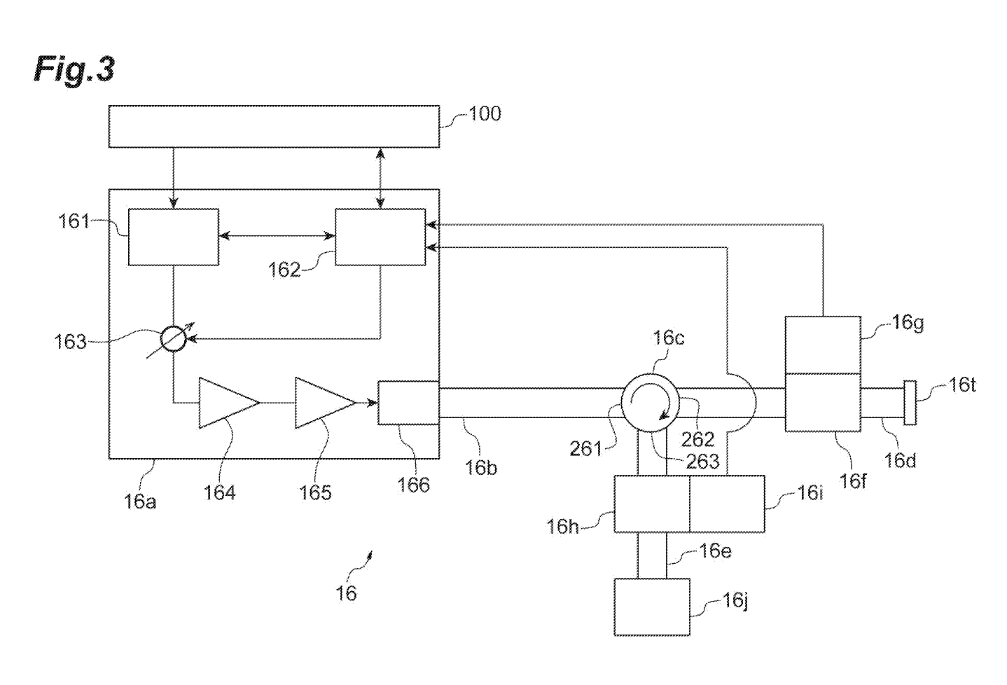

FIG. 3 is a diagram illustrating a microwave output device of a second example. As illustrated in FIG. 3, the microwave output device 16 of the second example is different from the microwave output device 16 of the first example in that the first directional coupler 16f is provided between one end and the other end of the waveguide 16d.

[Third Example of Microwave Output Device 16]

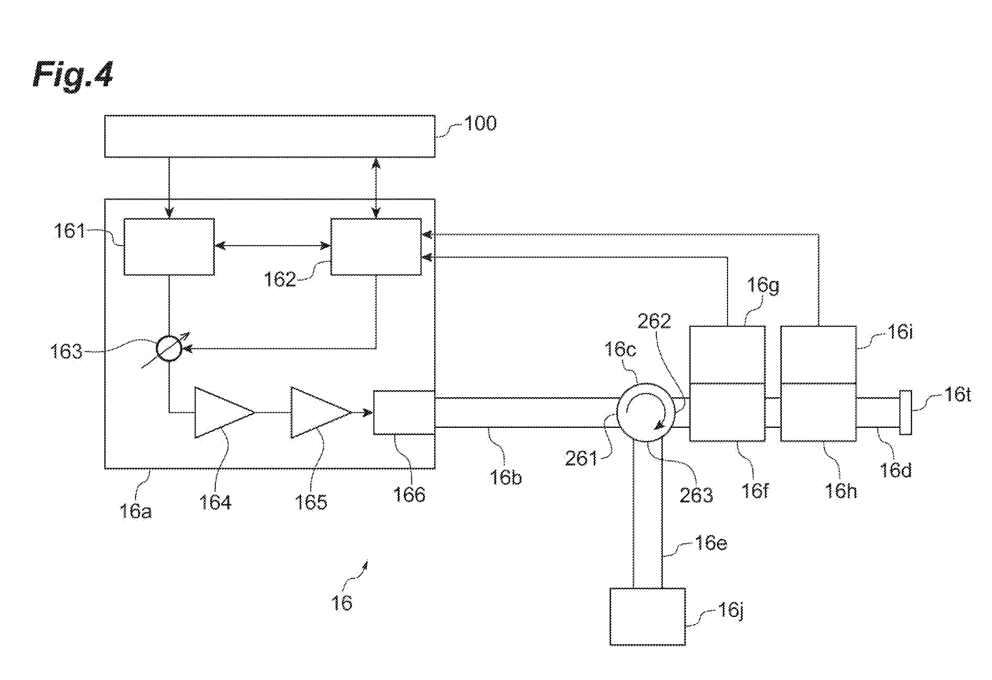

FIG. 4 is a diagram illustrating a microwave output device of a third example. As illustrated in FIG. 4, the microwave output device 16 of the third example is different from the microwave output device 16 of the first example in that both of the first directional coupler 16f and the second directional coupler 16h are provided between one end and the other end of the waveguide 16d.

Hereinafter, a description will be made of a first example of the first measurement unit 16g and a first example of the second measurement unit 16i of the microwave output device 16.

[First Example of First Measurement Unit 16g]

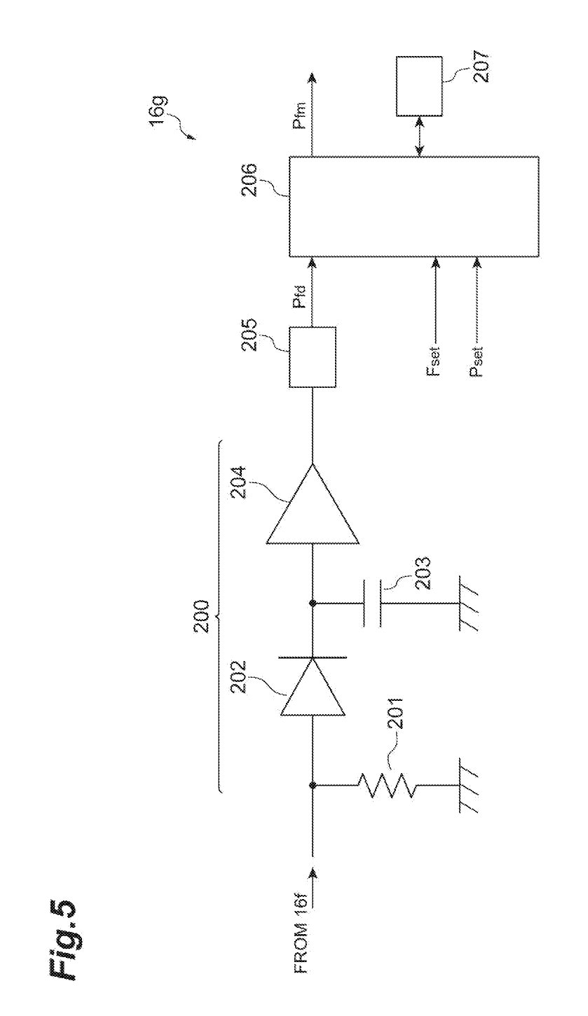

FIG. 5 is a diagram illustrating a first measurement unit of a first example. As illustrated in FIG. 5, in the first example, the first measurement unit 16g includes a first wave detection unit 200, a first A/D converter 205, and a first processing unit 206. The first wave detection unit 200 generates an analog signal corresponding to a power of a part of a travelling wave output from the first directional coupler 16f by using diode detection. The first wave detection unit 200 includes a resistive element 201, a diode 202, a capacitor 203, and an amplifier 204. One end of the resistive element 201 is connected to an input of the first measurement unit 16g. A part of a travelling wave output from the first directional coupler 16f is input to the input. The other end of the resistive element 201 is connected to the ground. The diode 202 is, for example, a low barrier Schottky diode. An anode of the diode 202 is connected to the input of the first measurement unit 16g. A cathode of the diode 202 is connected to an input of the amplifier 204. The cathode of the diode 202 is connected to one end of the capacitor 203. The other end of the capacitor 203 is connected to the ground. An output of the amplifier 204 is connected to an input of the first A/D converter 205. An output of the first A/D converter 205 is connected to the first processing unit 206.

In the first measurement unit 16g of the first example, an analog signal (voltage signal) corresponding to a power of a part of a travelling wave from the first directional coupler 16f is obtained through rectification in the diode 202, smoothing in the capacitor 203, and amplification in the amplifier 204. The analog signal is converted into a digital value P_{fd} in the first A/D converter 205. The digital value P_{fd} has a value corresponding to a power of the part of the travelling wave from the first directional coupler 16f. The digital value P_{fd} is input to the first processing unit 206.

The first processing unit 206 is configured with a processor such as a CPU. The first processing unit 206 is connected to a storage device 207. The storage device 207 stores a plurality of first correction coefficients for correcting the digital value P_{fd} to a power of a travelling wave at the output 16t. A set frequency Fₛₑₜ and a set power Pₛₑₜ designated for the microwave generation unit 16a are designated for the first processing unit 206 by the controller 100. The first processing unit 206 selects one or more first correction coefficients associated with the set frequency Fₛₑₜ and the set power Pₛₑₜ from among the plurality of first correction coefficients, and determines a first measured value Pₘ by multiplying the selected first correction coefficients by the digital value P_{fd}.

In one example, a plurality of preset first correction coefficients k_{f}(F,P) are stored in the storage device 207. Here, F indicates a frequency, and the number of F is the number of a plurality of frequencies which are able to be designated for the microwave generation unit 16a. P indicates power, and the number of P is the number of a plurality of power levels which are able to be designated for the microwave generation unit 16a.

In a case where the plurality of first correction coefficients k_{f}(F,P) are stored in the storage device 207, the first processing unit 206 selects k_{f}(Fₛₑₜ,Pₛₑₜ), and determines the first measured value P_{fm} by performing calculation of P_{fm}=k_{f}(Fₛₑₜ,Pₛₑₜ)×P_{fd}.

In another example, a plurality of first coefficients k1_{f}(F) and a plurality of second coefficients k2_{f}(P) are stored as the plurality of first correction coefficients in the storage device 207. Here, F and P are the same as F and P in the first correction coefficients k_{f}(F,P).

In a case where the plurality of first coefficients k1_{f}(F) and the plurality of second coefficients k2_{f}(P) are stored as the plurality of first correction coefficients in the storage device 207, the first processing unit 206 selects k1ₜ(Fₛₑ) and k2_{f}(Pₛₑₜ), and determines the first measured value P_{fm} by performing calculation of P_{fm}=k1_{f}(Fₛₑₜ)×k2_{f}(Pₛₑₜ)×P_{fd}.

[First Example of Second Measurement Unit 16i]

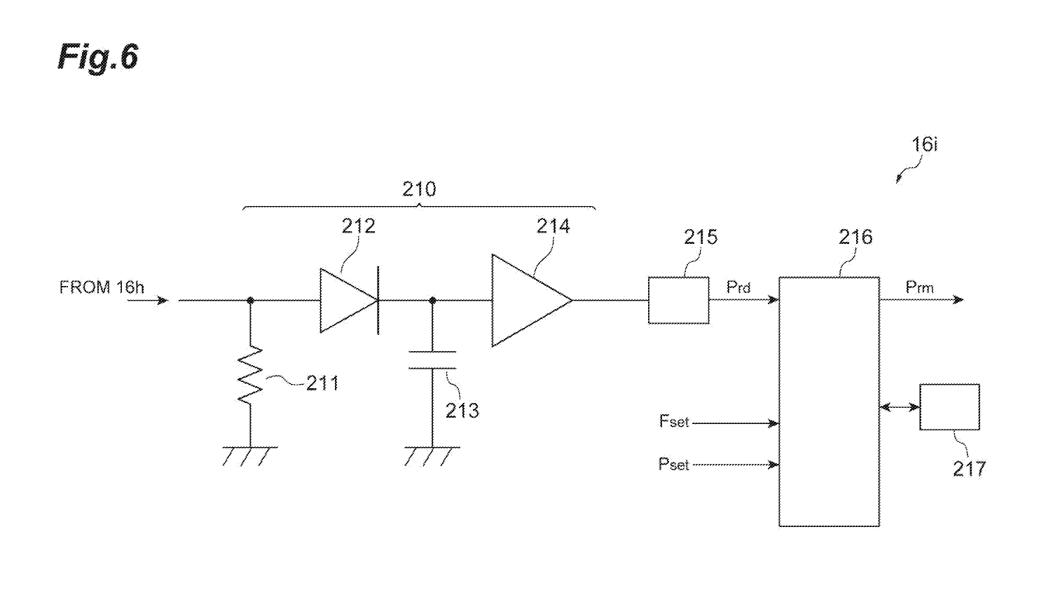

FIG. 6 is a diagram illustrating a second measurement unit of a first example. As illustrated in FIG. 6, in the first example, the second measurement unit 16i includes a second wave detection unit 210, a second A/D converter 215, and a second processing unit 216. In the same manner as the first wave detection unit 200, the second wave detection unit 210 generates an analog signal corresponding to a power of a part of a reflected wave output from the second directional coupler 16h by using diode detection. The second wave detection unit 210 includes a resistive element 211, a diode 212, a capacitor 213, and an amplifier 214. One end of the resistive element 211 is connected to an input of the second measurement unit 16i. A part of a reflected wave output from the second directional coupler 16h is input to the input. The other end of the resistive element 211 is connected to the ground. The diode 212 is, for example, a low barrier Schottky diode. An anode of the diode 212 is connected to the input of the second measurement unit 16i. A cathode of the diode 212 is connected to an input of the amplifier 214. The cathode of the diode 212 is connected to one end of the capacitor 213. The other end of the capacitor 213 is connected to the ground. An output of the amplifier 214 is connected to an input of the second A/D converter 215. An output of the second A/D converter 215 is connected to the second processing unit 216.

In the second measurement unit 16i of the first example, an analog signal (voltage signal) corresponding to a power of a part of a reflected wave from the second directional coupler 16h is obtained through rectification in the diode 212, smoothing in the capacitor 213, and amplification in the amplifier 214. The analog signal is converted into a digital value P_{rd} in the second A/D converter 215. The digital value P_{rd} has a value corresponding to a power of the part of the reflected wave from the second directional coupler 16h. The digital value P_{rd} is input to the second processing unit 216.

The second processing unit 216 is configured with a processor such as a CPU. The second processing unit 216 is connected to a storage device 217. The storage device 217 stores a plurality of second correction coefficients for correcting the digital value P_{rd} to a power of a reflected wave at the output 16t. The set frequency Fₛₑₜ and the set power Pₛₑₜ designated for the microwave generation unit 16a are designated for the second processing unit 216 by the controller. The second processing unit 216 selects one or more second correction coefficients associated with the set frequency Fₛₑₜ and the set power Pₛₑₜ from among the plurality of second correction coefficients, and determines a second measured value Pᵣₘ by multiplying the selected second correction coefficients by the digital value P_{rd}.

In one example, a plurality of preset second correction coefficients kᵣ(F,P) are stored in the storage device 217. Here, F and P are the same as F and P in the first correction coefficients k_{f}(F,P).

In a case where the plurality of second correction coefficients kᵣ(F,P) are stored in the storage device 217, the second processing unit 216 selects kᵣ(Fₛₑₜ,Pₛₑₜ), and determines the second measured value Pᵣₘ by performing calculation of Pᵣₘ=kᵣ(Fₛₑₜ,Pₛₑₜ)×P_{rd}.

In another example, a plurality of third coefficients k1ᵣ(F) and a plurality of fourth coefficients k2ᵣ(P) are stored as the plurality of second correction coefficients in the storage device 217. Here, F and P are the same as F and P in the first correction coefficients k_{f}(F,P).

In a case where the plurality of third coefficients k1ᵣ(F) and the plurality of fourth coefficients k2ᵣ(P) are stored as the plurality of second correction coefficients in the storage device 217, the second processing unit 216 selects k1ᵣ(Fₛₑₜ) and k2ᵣ(Pₛₑₜ), and determines the second measured value Pᵣₘ by performing calculation of Pᵣₘ=k1ᵣ(Fₛₑₜ)×k2ᵣ(Pₛₑₜ)×P_{rd}.

[Method of Preparing Plural First Correction Coefficients k_{f}(F,P)]

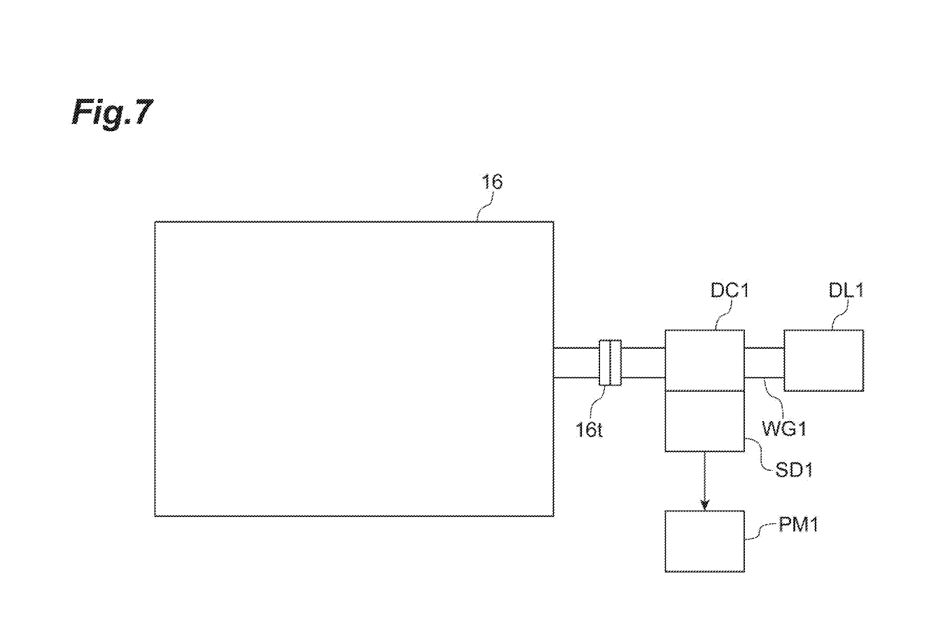

Hereinafter, a description will be made of a method of preparing a plurality of first correction coefficients. FIG. 7 is a diagram illustrating a configuration of a system including a microwave output device in a case where a plurality of first correction coefficients are prepared. As illustrated in FIG. 7, in order to prepare a plurality of first correction coefficients, one end of a waveguide WG1 is connected to the output 16t of the microwave output device 16. A dummy load DL1 is connected to the other end of the waveguide WG1. A directional coupler DC1 is provided between one end and the other end of the waveguide WG1. A sensor SD1 is connected to the directional coupler DC1. The sensor SD1 is connected to a power meter PM1. The directional coupler DC1 branches a part of a travelling wave propagating through the waveguide WG1. The part of the travelling wave branched by the directional coupler DC1 is input to the sensor SD1. The sensor SD1 is, for example, a thermocouple type sensor, generates electromotive force which is proportional to a power of a received microwave to provide a DC output. The power meter PM1 determines the power P_{fs} of a travelling wave at the output 16t on a basis of the DC output from the sensor SD1.

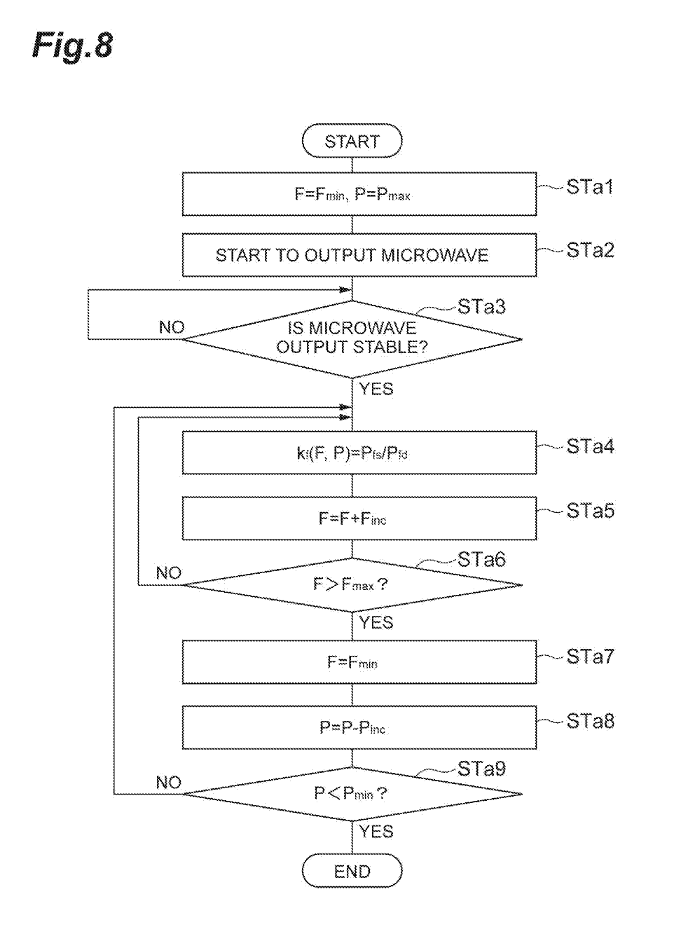

FIG. 8 is a flowchart illustrating a method of preparing a plurality of first correction coefficients k_{f}(F,P). In the method of preparing a plurality of first correction coefficients k_{f}(F,P), the system illustrated in FIG. 7 is prepared. As illustrated in FIG. 8, in step STa1, the frequency F is set to Fₘᵢₙ, and the power P is set to Pₘₐₓ. In other words, Fₘᵢₙ, is designated as a set frequency, and Pₘₐₓ is designated as a set power, for the microwave generation unit 16a. Fₘᵢₙ is the minimum set frequency which is able to be designated for the microwave generation unit 16a, and Pₘₐₓ is the maximum set power which is able to be designated for the microwave generation unit 16a.

In the subsequent step STa2, the microwave generation unit 16a starts to output a microwave. In the subsequent step STa3, it is determined whether or not output of the microwave is stable. For example, it is determined whether or not a power obtained in the power meter PM1 is stable. In a case where the output of the microwave is stable, in the subsequent step STa4, the power P_{fs} is obtained by the power meter PM1, the digital value P_{fd} is obtained by the first measurement unit 16g, and the first correction coefficient k_{f}(F,P) is obtained through calculation of k_{f}(F,P)=P_{fs}/P_{fd}.

In the subsequent step STa5, the frequency F is incremented by a predetermined value F_{inc}. In the subsequent step STa6, it is determined whether or not F is higher than Fₘₐₓ. Fₘₐₓ is the maximum set frequency which is able to be designated for the microwave generation unit 16a. In a case where the frequency F is equal to or lower than Fₘₐₓ, a set frequency of a microwave output from the microwave generation unit 16a is changed to the frequency F. The process from step STa4 is then continued. On the other hand, in a case where it is determined that F is higher than Fₘₐₓ in step STa6, the frequency F is set to Fₘᵢₙ in step STa7, and the power P is reduced by a predetermined value P_{inc} in step STa8.

In the subsequent step STa9, it is determined whether or not the power P is lower than Pₘᵢₙ. Pₘᵢₙ is the minimum set power which is able to be designated for the microwave generation unit 16a. In a case where it is determined that P is equal to or higher than Pₘᵢₙ in step STa9, a set frequency of a microwave output from the microwave generation unit 16a is changed to the frequency F, and a set power of the microwave is changed to the power P. The process from step STa4 is then continued. On the other hand, in a case where it is determined that P is lower than Pₘᵢₙ in step STa9, preparation of the plurality of first correction coefficients k_{f}(F,P) is completed. In other words, there is completion of preparation of a plurality of first correction coefficients k_{f}(F,P) for correcting the digital value P_{fd} to a power of a travelling wave at the output 16t of the microwave output device 16 according to the set frequency and the set power designated for the microwave generation unit 16a.

[Method of Preparing Plural Second Correction Coefficients kᵣ(F,P)]

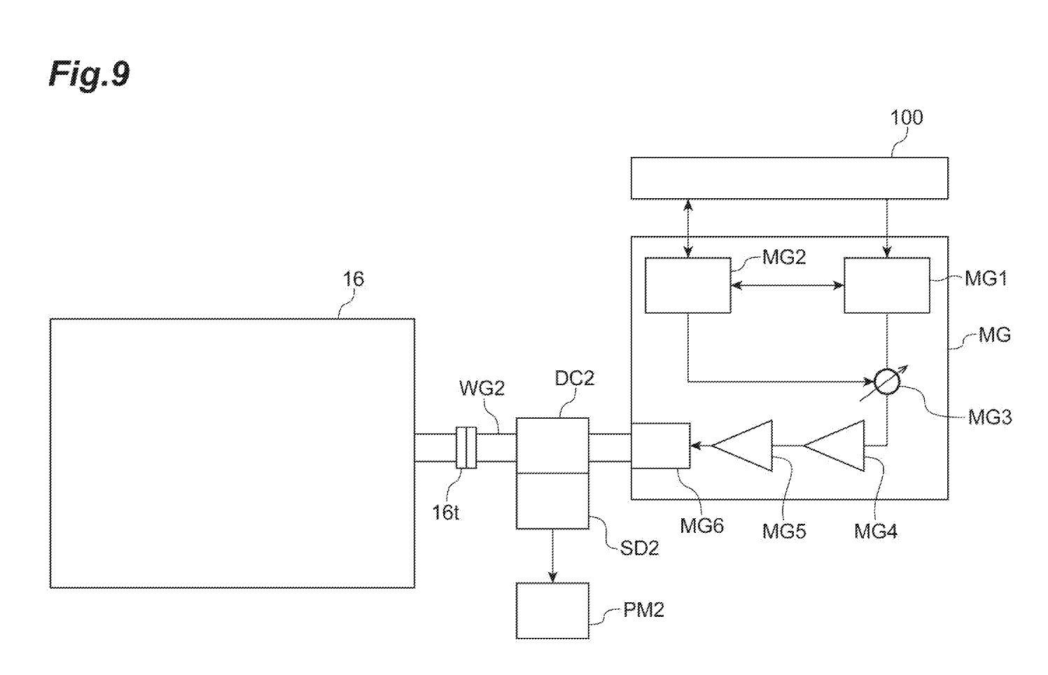

FIG. 9 is a diagram illustrating a configuration of a system including a microwave output device in a case where a plurality of second correction coefficients are prepared. As illustrated in FIG. 9, in order to prepare a plurality of second correction coefficients, one end of a waveguide WG2 is connected to the output 16t of the microwave output device 16. The other end of the waveguide WG2 is connected to a microwave generation unit MG having the same configuration as that of the microwave generation unit 16a of the microwave output device 16. The microwave generation unit MG outputs a microwave simulating a reflected wave to the waveguide WG2. The microwave generation unit MG includes a waveform generation unit MG1 which is the same as the waveform generation unit 161, a power control unit MG2 which is the same as the power control unit 162, an attenuator MG3 which is the same as the attenuator 163, an amplifier MG4 which is the same as the amplifier 164, an amplifier MG5 which is the same as the amplifier 165, and a mode converter MG6 which is the same as the mode converter 166.

A directional coupler DC2 is provided between one end and the other end of the waveguide WG2. A sensor SD2 is connected to the directional coupler DC2. The sensor SD2 is connected to a power meter PM2. The directional coupler DC2 branches a part of a microwave which is generated by the microwave generation unit MG and propagates toward the microwave output device 16 through the waveguide WG2. The part of the microwave branched by the directional coupler DC2 is input to the sensor SD2. The sensor SD2 is, for example, a thermocouple type sensor, generates electromotive force which is proportional to a power of the part of the received microwave, to provide a DC output. The power meter PM2 determines the power Pᵣₛ of a microwave at the output 16t on a basis of the DC output from the sensor SD2. The power of a microwave determined by the power meter PM2 corresponds to a power of a reflected wave at the output 16t.

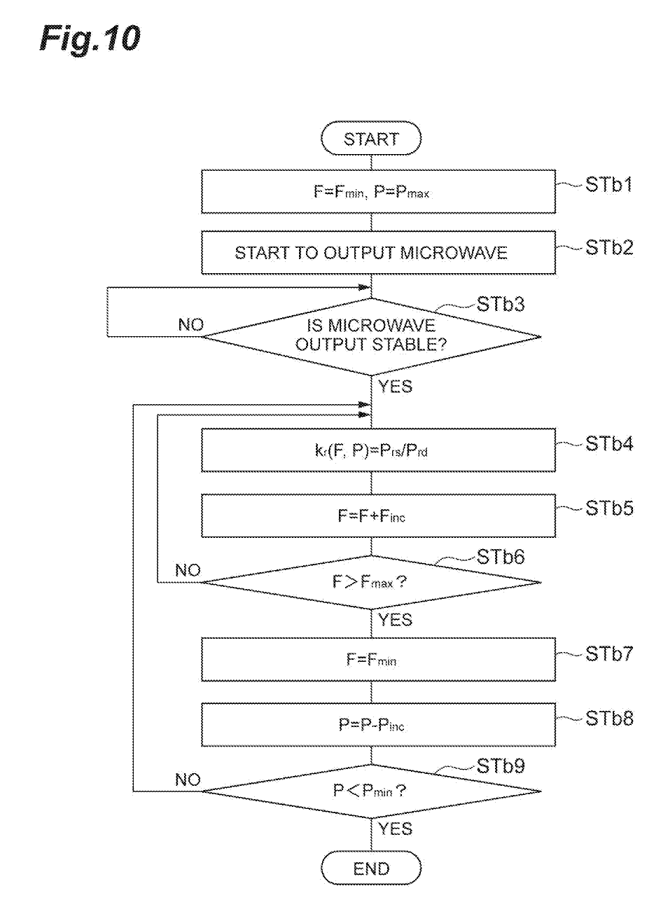

FIG. 10 is a flowchart illustrating a method of preparing a plurality of second correction coefficients kᵣ(F,P). In the method of preparing a plurality of second correction coefficients kᵣ(F,P), the system illustrated in FIG. 9 is prepared. As illustrated in FIG. 10, in step STb1, the frequency F is set to Fₘᵢₙ, and the power P is set to Pₘₐₓ. In other words, Fₘᵢₙ is designated as a set frequency, and Pₘₐₓ is designated as a set power, for the microwave generation unit MG.

In the subsequent step STb2, the microwave generation unit MG starts to output a microwave. In the subsequent step STb3, it is determined whether or not output of the microwave is stable. For example, it is determined whether or not a power obtained in the power meter PM2 is stable. In a case where the output of the microwave is stable, in the subsequent step STb4, the power Pᵣₛ is obtained by the power meter PM2, the digital value P_{rd} is obtained by the second measurement unit 16i, and the second correction coefficient kᵣ(F,P) is obtained through calculation of kᵣ(F,P)=Pᵣₛ/P_{rd}.

In the subsequent step STb5, the frequency F is incremented by a predetermined value F_{inc}. In the subsequent step STb6, it is determined whether or not F is higher than Fₘₐₓ. In a case where the frequency F is equal to or lower than Fₘₐₓ, a set frequency of a microwave output from the microwave generation unit MG is changed to the frequency F. The process from step STb4 is then continued. On the other hand, in a case where it is determined that F is higher than Fₘₐₓ in step STb6, the frequency F is set to Fₘᵢₙ, in step STb7, and the power P is reduced by a predetermined value P_{inc} in step STb8.

In the subsequent step STb9, it is determined whether or not the power P is lower than Pₘᵢₙ. In a case where it is determined that P is equal to or higher than Pₘᵢₙ in step STb9, a set frequency of a microwave output from the microwave generation unit MG is changed to the frequency F, and a set power of the microwave is changed to the power P. The process from step STb4 is then continued. On the other hand, in a case where it is determined that P is lower than Pₘᵢₙ in step STb9, preparation of a plurality of second correction coefficients kᵣ(F,P) is completed. In other words, there is completion of preparation of a plurality of second correction coefficients kᵣ(F,P) for correcting the digital value P_{rd} to a power of a reflected wave at the output 16t of the microwave output device 16 according to the set frequency and the set power designated for the microwave generation unit 16a.

[Method of Preparing Plural First Coefficients k1_{f}(F) and Plural Second Coefficients k2_{f}(P)]

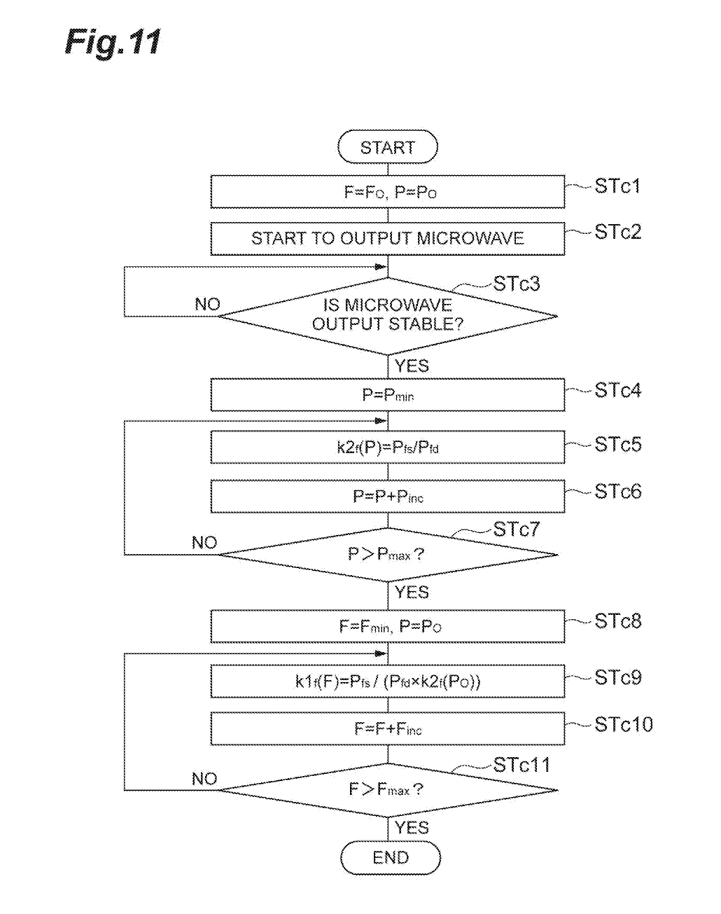

FIG. 11 is a flowchart illustrating a method of preparing a plurality of first coefficients k1_{f}(F) and a plurality of second coefficients k2_{f}(P) as a plurality of first correction coefficients. In the method of preparing a plurality of first coefficients k1_{f}(F) and a plurality of second coefficients k2_{f}(P), the system illustrated in FIG. 7 is prepared. As illustrated in FIG. 11, in step STc1, the frequency F is set to F_{O}, and the power P is set to P_{O}. In other words, F_{O} is designated as a set frequency, and P_{O} is designated as a set power, for the microwave generation unit 16a. F_{O} is a frequency of a microwave at which an error between the digital value P_{fd} and the power P_{fs} is substantially 0 even if any set power is designated for the microwave generation unit 16a. P_{O} is a power of a microwave at which an error between the digital value P_{fd} and the power P_{fs} is substantially 0 even if any set frequency is designated for the microwave generation unit 16a.

In the subsequent step STc2, the microwave generation unit 16a starts to output a microwave. In the subsequent step STc3, it is determined whether or not output of the microwave is stable. For example, it is determined whether or not a power obtained in the power meter PM1 is stable. In a case where the output of the microwave is stable, in the subsequent step STc4, the power P is set to Pₘᵢₙ, and a set power of a microwave output from the microwave generation unit 16a is changed to Pₘᵢₙ.

In the subsequent step STc5, the power P_{fs} is obtained by the power meter PM1, the digital value P_{fd} is obtained by the first measurement unit 16g, and the second coefficient k2_{f}(P) is obtained through calculation of k2_{f}(P)=P_{fs}/P_{fd}. In the subsequent step STc6, the power P is incremented by a predetermined value P_{inc}. In the subsequent step STc7, it is determined whether or not the power P is higher than Pₘₐₓ. In a case where it is determined that the power P is equal to or lower than Pₘₐₓ in step STc7, a set power of a microwave output from the microwave generation unit 16a is changed to the power P, and the process from step STc5 is repeated. On the other hand, in a case where it is determined that P is higher than Pₘₐₓ in step STc7, preparation of a plurality of second coefficients k2_{f}(P) is completed.

In the subsequent step STc8, the frequency F is set to Fₘᵢₙ, and the power P is set to P_{O}. In other words, Fₘᵢₙ is designated as a set frequency, and P_{O} is designated as a set power, for the microwave generation unit 16a.

In the subsequent step STc9, the power P_{fs} is obtained by the power meter PM1, the digital value P_{fd} is obtained by the first measurement unit 16g, and the first coefficients k1_{f}(F) is obtained through calculation of k1_{f}(F)=P_{fs}/(P_{fd}×k2_{f}(P_{O})). In the subsequent step STc10, the frequency F is incremented by a predetermined value Fᵢₙ. In the subsequent step STc11, it is determined whether or not the frequency F is higher than Fₘₐₓ. In a case where it is determined that the frequency F is equal to or lower than Fₘᵢₙ in step STc11, a set frequency of a microwave output from the microwave generation unit 16a is changed to the frequency F, and the process from step STc9 is repeated. On the other hand, in a case where it is determined that F is higher than Fₘₐₓ in step STc11, preparation of a plurality of first coefficients k1_{f}(F) is completed.

[Method of Preparing Plural Third Coefficients k1ᵣ(F) and Plural Fourth Coefficients k2ᵣ(P)]

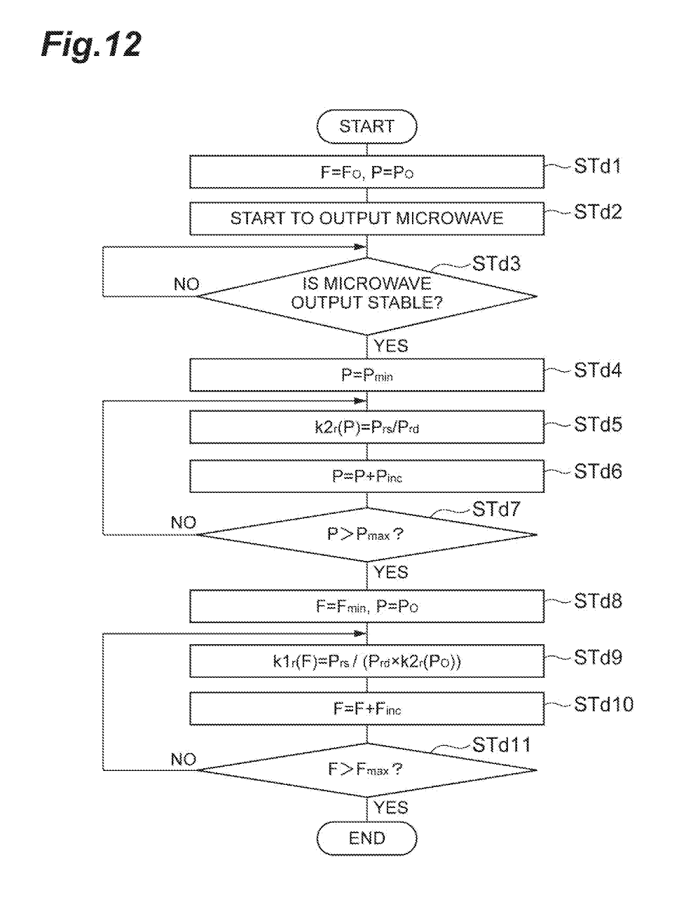

FIG. 12 is a flowchart illustrating a method of preparing a plurality of third coefficients k1ᵣ(F) and a plurality of fourth coefficients k2ᵣ(P) as a plurality of second correction coefficients. In the method of preparing a plurality of third coefficients k1ᵣ(F) and a plurality of fourth coefficients k2ᵣ(P), the system illustrated in FIG. 9 is prepared. As illustrated in FIG. 12, in step STd1, the frequency F is set to F_{O}, and the power P is set to P_{O}. In other words, F_{O} is designated as a set frequency, and P_{O} is designated as a set power, for the microwave generation unit MG.

In the subsequent step STd2, the microwave generation unit MG starts to output a microwave. In the subsequent step STd3, it is determined whether or not output of the microwave is stable. For example, it is determined whether or not a power obtained in the power meter PM2 is stable. In a case where the output of the microwave is stable, in the subsequent step STd4, the power P is set to Pₘᵢₙ, and a set power of a microwave output from the microwave generation unit MG is changed to Pₘᵢₙ.

In the subsequent step STd5, the power Pᵣₛ is obtained by the power meter PM2, the digital value P_{rd} is obtained by the second measurement unit 16i, and the fourth coefficients k2ᵣ(P) is obtained through calculation of k2ᵣ(P)=Pᵣₛ/P_{rd}. In the subsequent step STd6, the power P is incremented by a predetermined value P_{inc}. In the subsequent step STd7, it is determined whether or not the power P is higher than Pₘₐₓ. In a case where it is determined that the power P is equal to or lower than Pₘₐₓ in step STd7, a set power of a microwave output from the microwave generation unit MG is changed to the power P, and the process from step STd5 is repeated. On the other hand, in a case where it is determined that P is higher than Pₘₐₓ in step STd7, preparation of a plurality of fourth coefficients k2ᵣ(P) is completed.

In the subsequent step STd8, the frequency F is set to Fₘᵢₙ, and the power P is set to P_{O}. In other words, Fₘᵢₙ is designated as a set frequency, and P_{O} is designated as a set power, for the microwave generation unit MG.

In the subsequent step STd9, the power Pᵣₛ is obtained by the power meter PM2, the digital value P_{rd} is obtained by the second measurement unit 16i, and the third coefficients k1ᵣ(F) is obtained through calculation of k1ᵣ(F)=Pᵣₛ/(P_{rd}×k2ᵣ(P_{O})). In the subsequent step STd10, the frequency F is incremented by a predetermined value F_{inc}. In the subsequent step STd11, it is determined whether or not the frequency F is higher than Fₘₐₓ. In a case where it is determined that the frequency F is equal to or lower than Fₘₐₓ in step STd11, a set frequency of a microwave output from the microwave generation unit MG is changed to the frequency F, and the process from step STd9 is repeated. On the other hand, in a case where it is determined that F is higher than Fₘₐₓ in step STd11, preparation of a plurality of third coefficients k1ᵣ(F) is completed.

The digital value P_{fd} obtained by converting by the first A/D converter 205 an analog signal generated by the first wave detection unit 200 of the first measurement unit 16g of the first example illustrated in FIG. 5 has an error with respect to a power of a travelling wave at the output 16t. The error has dependency on a set frequency and a set power of a microwave. A factor of the dependency lies in diode detection. In the first measurement unit 16g of the first example, one or more first correction coefficients, that is, k_{f}(Fₛₑₜ,Pₛₑₜ) or k1_{f}(Fₛₑₜ) and k2_{f}(Pₛₑₜ) associated with the set frequency Fₛₑₜ and the set power Pₛₑₜ designated by the controller 100 are selected from among the plurality of first correction coefficients which are prepared in advance to reduce the error. The selected one or more first correction coefficients are then multiplied by the digital value P_{fd}. Consequently, the first measured value P_{fm} is obtained. Therefore, an error between a power of a travelling wave at the output 16t and the first measured value P_{fm} obtained on a basis of a part of a travelling wave output from the first directional coupler 16f is reduced.

The number of the plurality of first correction coefficients k_{f}(F,P) is a product of the number of frequencies which are able to be designated as a set frequency and the number of power levels which are able to be designated as a set power. On the other hand, in a case where the plurality of first coefficients k1_{f}(F) and the plurality of second coefficients k2_{f}(P) are used, the number of the plurality of first correction coefficients is a sum of the number of the plurality of first coefficients k1_{f}(F) and the number of the plurality of second coefficients k2_{f}(P). Therefore, in a case where the plurality of first coefficients k1_{f}(F) and the plurality of second coefficients k2_{f}(P) are used, the number of the plurality of first correction coefficients can be reduced compared with a case of using the plurality of first correction coefficients k_{f}(F,P).

The digital value P_{rd} obtained by converting by the second A/D converter 215 an analog signal generated by the second wave detection unit 210 of the second measurement unit 16i of the first example illustrated in FIG. 6 has an error with respect to a power of a reflected wave at the output 16t. The error has dependency on a set frequency and a set power of a microwave. A factor of the dependency lies in diode detection. In the second measurement unit 16i of the first example, one or more second correction coefficients, that is, kᵣ(Fₛₑₜ,Pₛₑₜ) or k1ᵣ(Fₛₑₜ) and k2ᵣ(Pₛₑₜ) associated with the set frequency Fₛₑₜ and the set power Pₛₑₜ designated by the controller 100 are selected from among a plurality of second correction coefficients which are prepared in advance to reduce the error. The selected one or more second correction coefficients are then multiplied by the digital value P_{rd}. Consequently, the second measured value Pᵣₘ is obtained. Therefore, an error between a power of a reflected wave at the output 16t and the second measured value Pᵣₘ obtained on a basis of a part of a reflected wave output from the second directional coupler 16h is reduced.

The number of the plurality of second correction coefficients kᵣ(F,P) is a product of the number of frequencies which are able to be designated as a set frequency and the number of power levels which are able to be designated as a set power. On the other hand, in a case where the plurality of third coefficients k1ᵣ(F) and the plurality of fourth coefficients k2ᵣ(P) are used, the number of the plurality of second correction coefficients is a sum of the number of the plurality of third coefficients k1ᵣ(F) and the number of the plurality of fourth coefficients k2ᵣ(P). Therefore, in a case where the plurality of third coefficients k1ᵣ(F) and the plurality of fourth coefficients k2ᵣ(P) are used, the number of the plurality of second correction coefficients can be reduced compared with a case of using the plurality of second correction coefficients kᵣ(F,P).

In the microwave output device 16, since the power control unit 162 controls a power of a microwave output from the microwave output device 16 to make a difference between the first measured value P_{fm} and the second measured value Pᵣₘ closer to the set power designated by the controller 100, a load power of a microwave supplied to a load coupled to the output 16t can be made closer to the set power.

Hereinafter, a description will be made of a second example of the first measurement unit 16g and a second example of the second measurement unit 16i of the microwave output device 16.

[Second Example of First Measurement Unit 16g]

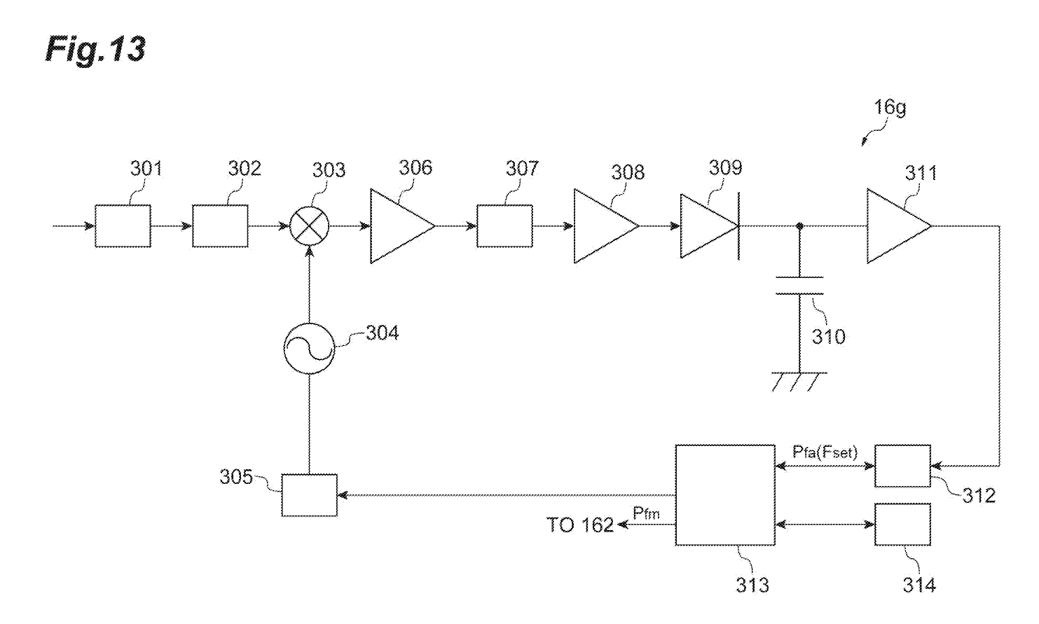

FIG. 13 is a diagram illustrating a first measurement unit of a second example. As illustrated in FIG. 13, in the second example, the first measurement unit 16g includes an attenuator 301, a low-pass filter 302, a mixer 303, a local oscillator 304, a frequency sweeping controller 305, an IF amplifier 306 (intermediate frequency amplifier), an IF filter 307 (intermediate frequency filter), a log amplifier 308, a diode 309, a capacitor 310, a buffer amplifier 311, an A/D converter 312, and a first processing unit 313.

The attenuator 301, the low-pass filter 302, the mixer 303, the local oscillator 304, the frequency sweeping controller 305, the IF amplifier 306 (intermediate frequency amplifier), the IF filter 307 (intermediate frequency filter), the log amplifier 308, the diode 309, the capacitor 310, the buffer amplifier 311, and the A/D converter 312 configure a first spectrum analysis unit. The first spectrum analysis unit obtains a digital value P_{fa}(Fₛₑₜ) indicating a power of a part of a travelling wave output from the first directional coupler 16f.

The part of the travelling wave output from the first directional coupler 16f is input to an input of the attenuator 301. An analog signal attenuated by the attenuator 301 is filtered in the low-pass filter 302. A signal filtered in the low-pass filter 302 is input to the mixer 303. In the meantime, the local oscillator 304 changes a frequency of a signal to be transmitted therefrom under the control of the frequency sweeping controller 305 in order to convert a part of a travelling wave which is input to the attenuator 301 into a signal having a predetermined intermediate frequency. The mixer 303 mixes the signal from the low-pass filter 302 with the signal from the local oscillator 304 to generate a signal having a predetermined intermediate frequency.

The signal from the mixer 303 is amplified by the IF amplifier 306, and the signal amplified by the IF amplifier 306 is filtered in the IF filter 307. The signal filtered in the IF filter 307 is amplified by the log amplifier 308. The signal amplified by the log amplifier 308 is converted into an analog signal (voltage signal) through rectification in the diode 309, smoothing in the capacitor 310, and amplification in the buffer amplifier 311. The analog signal from the buffer amplifier 311 is converted into the digital value P_{fa}(Fₛₑₜ) by the A/D converter 312. The digital value fₐ(Fₛₑₜ) is input to the first processing unit 313.

The first processing unit 313 is configured with a processor such as a CPU. The first processing unit 313 is connected to a storage device 314. In one example, a plurality of preset first correction coefficients k_{sf}(F) are stored in the storage device 314. The plurality of first correction coefficients k_{sf}(F) are coefficients for correcting the digital value P_{fa}(Fₛₑₜ) to a power of a travelling wave at the output 16t. The first processing unit 313 obtains the first measured value P_{fm} through multiplication of one first correction coefficient k_{sf}(Fₛₑₜ) among the plurality of first correction coefficients k_{sf}(F) by the digital value P_{fa}(Fₛₑₜ), that is, k_{sf}(Fₛₑₜ)×P_{fa}(Fₛₑₜ).

[Second Example of Second Measurement Unit 16i]

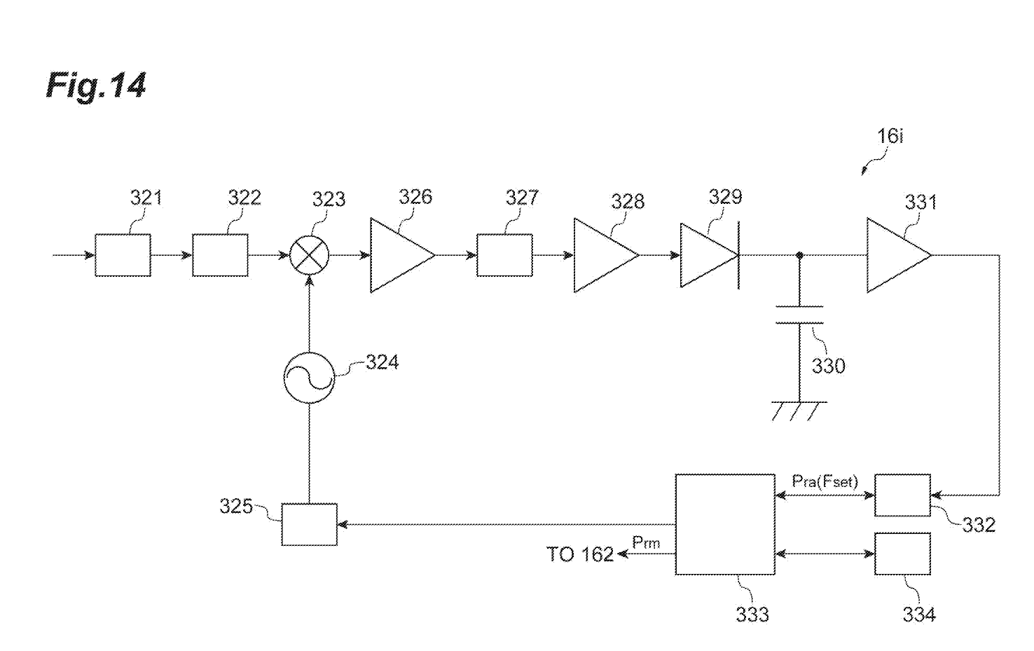

FIG. 14 is a diagram illustrating a second measurement unit of a second example. As illustrated in FIG. 14, in the second example, the second measurement unit 16i includes an attenuator 321, a low-pass filter 322, a mixer 323, a local oscillator 324, a frequency sweeping controller 325, an IF amplifier 326 (intermediate frequency amplifier), an IF filter 327 (intermediate frequency filter), a log amplifier 328, a diode 329, a capacitor 330, a buffer amplifier 331, an A/D converter 332, and a second processing unit 333.

The attenuator 321, the low-pass filter 322, the mixer 323, the local oscillator 324, the frequency sweeping controller 325, the IF amplifier 326 (intermediate frequency amplifier), the IF filter 327 (intermediate frequency filter), the log amplifier 328, the diode 329, the capacitor 330, the buffer amplifier 331, and the A/D converter 332 configure a second spectrum analysis unit. The second spectrum analysis unit obtains a digital value Pᵣₐ(Fₛₑₜ) indicating a power of a part of a reflected wave output from the second directional coupler 16h.

The part of the reflected wave output from the second directional coupler 16h is input to an input of the attenuator 321. An analog signal attenuated by the attenuator 321 is filtered in the low-pass filter 322. A signal filtered in the low-pass filter 322 is input to the mixer 323. In the meantime, the local oscillator 324 changes a frequency of a signal to be transmitted therefrom under the control of the frequency sweeping controller 325 in order to convert a part of a reflected wave which is input to the attenuator 321 into a signal having a predetermined intermediate frequency. The mixer 323 mixes the signal from the low-pass filter 322 with the signal from the local oscillator 324 to generate a signal having a predetermined intermediate frequency.

The signal from the mixer 323 is amplified by the IF amplifier 326, and the signal amplified by the IF amplifier 326 is filtered in the IF filter 327. The signal filtered in the IF filter 327 is amplified by the log amplifier 328. The signal amplified by the log amplifier 328 is converted into an analog signal (voltage signal) through rectification in the diode 329, smoothing in the capacitor 330, and amplification in the buffer amplifier 331. The analog signal from the buffer amplifier 331 is converted into the digital value Pᵣₐ(Fₛₑₜ) by the A/D converter 332. The digital value Pᵣₐ(Fₛₑₜ) is input to the second processing unit 333.

The second processing unit 333 is configured with a processor such as a CPU. The second processing unit 333 is connected to a storage device 334. In one example, a plurality of preset second correction coefficients kₛᵣ(F) are stored in the storage device 334. The plurality of second correction coefficients kₛᵣ(F) are coefficients for correcting the digital value Pᵣₐ(Fₛₑₜ) to a power of a reflected wave at the output 16t. The second processing unit 333 obtains the second measured value Pᵣₘ through multiplication of one second correction coefficient kₛᵣ(Fₛₑₜ) among the plurality of second correction coefficients kₛᵣ(F) by the digital value Pᵣₐ(Fₛₑₜ), that is, kₛᵣ(Fₛₑₜ)×Pᵣₐ(Fₛₑₜ).

[Method of Preparing Plural First Correction Coefficients k_{sf}(F)]

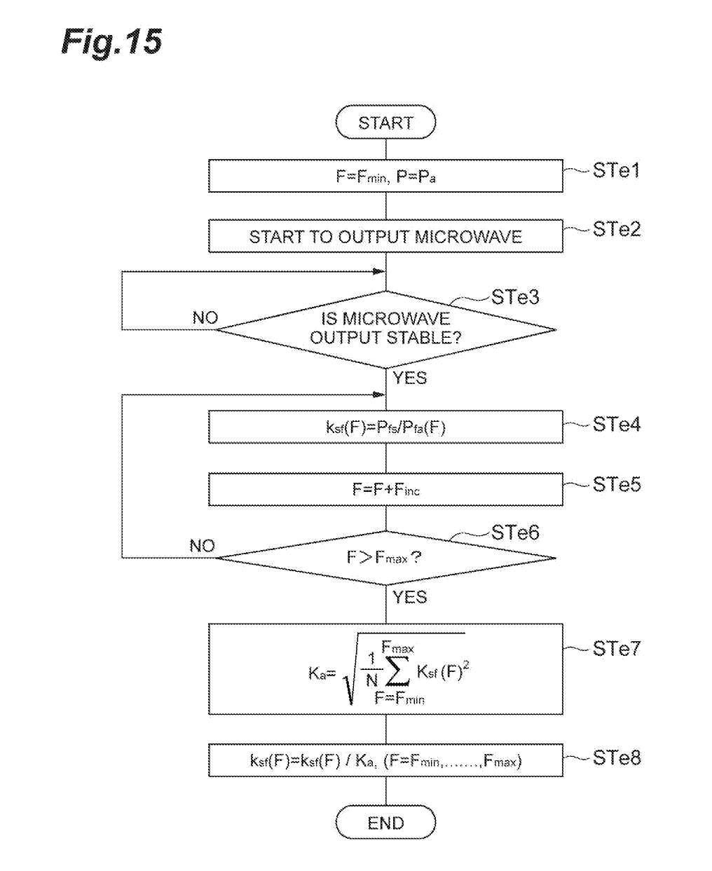

Hereinafter, a description will be made of a method of preparing a plurality of first correction coefficients k_{sf}(F). FIG. 15 is a flowchart illustrating a method of preparing a plurality of first correction coefficients k_{sf}(F). In the method of preparing a plurality of first correction coefficients k_{sf}(F), the system illustrated in FIG. 7 is prepared. As illustrated in FIG. 15, in step STe1, the frequency F is set to Fₘᵢₙ, and the power P is set to Pₐ. In other words, Fₘᵢₙ is designated as a set frequency, and Pₐ is designated as a set power, for the microwave generation unit 16a. Pₐ may be any power which is able to be designated for the microwave generation unit 16a.

In the subsequent step STe2, the microwave generation unit 16a starts to output a microwave. In the subsequent step STe3, it is determined whether or not output of the microwave is stable. For example, it is determined whether or not a power obtained in the power meter PM1 is stable.

In a case where the output of the microwave is stable, in the subsequent step STe4, the power P_{fs} is obtained by the power meter PM1, the digital value P_{fa}(F) is obtained by the first measurement unit 16g, and the first correction coefficient k_{sf}(F) is obtained through calculation of k_{sf}(F)=P_{fs}/P_{fa}(F). In the subsequent step STe5, the frequency F is incremented by a predetermined value F_{inc}. In the subsequent step STe6, it is determined whether or not F is higher than Fₘₐₓ. In a case where it is determined that the frequency F is equal to or lower than Fₘₐₓ in step STe6, a set frequency of a microwave output from the microwave generation unit 16a is changed to the frequency F, and the process from step STe4 is repeated. On the other hand, in a case where it is determined that F is higher than Fₘₐₓ in step STe6, the flow proceeds to a process in step STe7.

In step STe7, a root mean square Kₐ of a plurality of first correction coefficients kₛₜ(F) is obtained through calculation expressed by the following Equation (1).

$${K}_{a} = \sqrt{\frac{1}{N} {\sum }_{F = {F}_{m i n}}^{{F}_{m a x}} {{k}_{sf} ( F )}^{2 }} \qquad ( 1 )$$

In the subsequent step STe8, each of the plurality of first correction coefficients kₛₜ(F) is divided by Kₐ. Consequently, a plurality of first correction coefficients k_{sf}(F) are obtained.

[Method of Preparing Plural Second Correction Coefficients kₛᵣ(F)]

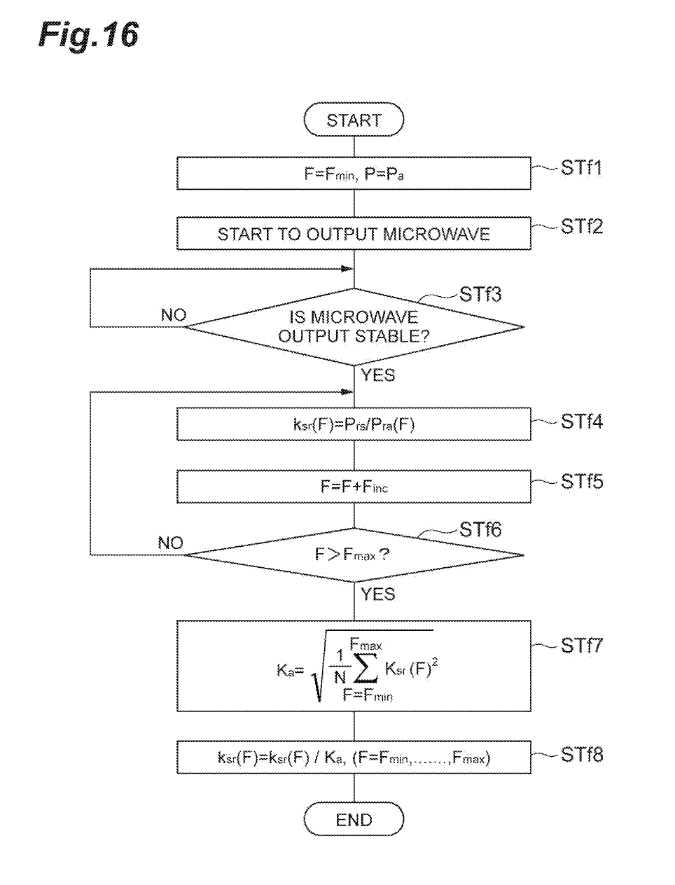

Hereinafter, a description will be made of a method of preparing a plurality of second correction coefficients kₛᵣ(F). FIG. 16 is a flowchart illustrating a method of preparing a plurality of second correction coefficients kₛᵣ(F). In the method of preparing a plurality of second correction coefficients kₛᵣ(F), the system illustrated in FIG. 9 is prepared. As illustrated in FIG. 16, in step STf1, the frequency F is set to Fₘᵢₙ, and the power P is set to Pₐ. In other words, Fₘᵢₙ is designated as a set frequency, and Pₐ is designated as a set power, for the microwave generation unit MG.

In the subsequent step STf2, the microwave generation unit MG starts to output a microwave. In the subsequent step STf3, it is determined whether or not output of the microwave is stable. For example, it is determined whether or not a power obtained in the power meter PM2 is stable.

In a case where the output of the microwave is stable, in the subsequent step STf4, the power Pᵣₛ is obtained by the power meter PM2, the digital value Pᵣₐ(F) is obtained by the second measurement unit 16i, and the second correction coefficients kₛᵣ(F) is obtained through calculation of kₛᵣ(F)=Pᵣₛ/Pᵣₐ(F). In the subsequent step STf5, the frequency F is incremented by a predetermined value F_{inc}. In the subsequent step STf6, it is determined whether or not F is higher than Fₘₐₓ. In a case where it is determined that the frequency F is equal to or lower than Fₘₐₓ in step STf6, a set frequency of a microwave output from the microwave generation unit MG is changed to the frequency F, and the process from step STf4 is repeated. On the other hand, in a case where it is determined that F is higher than Fₘₐₓ in step STf6, the flow proceeds to a process in step STf7.

In step STf7, a root mean square Kₐ of a plurality of second correction coefficients kₛᵣ(F) is obtained through calculation expressed by the following Equation (2).

$${K}_{a} = \sqrt{\frac{1}{N} {\sum }_{F = {F}_{m i n}}^{{F}_{m a x}} {{k}_{sr} ( F )}^{2 }} \qquad ( 2 )$$

In the subsequent step STf8, each of the plurality of second correction coefficients kₛᵣ(F) is divided by Kₐ. Consequently, a plurality of second correction coefficients kₛᵣ(F) are obtained.

In the first measurement unit 16g of the second example, the digital value P_{fa}(Fₛₑₜ) obtained through spectrum analysis in the first spectrum analysis unit is multiplied by one first correction coefficient k_{sf}(Fₛₑₜ) among a plurality of first correction coefficients k_{sf}(F). Consequently, the first measured value P_{fm} is obtained. Therefore, an error between a power of a travelling wave at the output 16t and the first measured value P_{fm} obtained on a basis of a part of a travelling wave output from the first directional coupler 16f is reduced.

In the second measurement unit 16i of the second example, the digital value Pᵣₐ(Fₛₑₜ) obtained through spectrum analysis in the second spectrum analysis unit is multiplied by one second correction coefficient kₛᵣ(Fₛₑₜ) among a plurality of second correction coefficients kₛᵣ(F). Consequently, the second measured value Pᵣₘ is obtained. Therefore, an error between a power of a reflected wave at the output 16t and the second measured value Pᵣₘ obtained on a basis of a part of a reflected wave output from the second directional coupler 16h is reduced.

Since the power control unit 162 controls a power of a microwave output from the microwave output device 16 to make a difference between the first measured value P_{fm} and the second measured value Pᵣₘ closer to the set power designated by the controller 100, a load power of a microwave supplied to a load coupled to the output 16t can be made closer to the set power.

### REFERENCE SIGNS LIST

1 PLASMA PROCESSING APPARATUS, 12 CHAMBER BODY, 14 STAGE, 16 MICROWAVE OUTPUT DEVICE, 16a MICROWAVE GENERATION UNIT, 16f FIRST DIRECTIONAL COUPLER, 16g FIRST MEASUREMENT UNIT, 16h SECOND DIRECTIONAL COUPLER, 16i SECOND MEASUREMENT UNIT, 16t OUTPUT, 18 ANTENNA, 20 DIELECTRIC WINDOW, 26 TUNER, 27 MODE CONVERTER, 28 COAXIAL WAVEGUIDE, 30 SLOT PLATE, 32 DIELECTRIC PLATE, 34 COOLING JACKET, 38 GAS SUPPLY SYSTEM, 58 RADIO FREQUENCY POWER SUPPLY, 60 MATCHING UNIT, 100 CONTROLLER, 161 WAVEFORM GENERATION UNIT, 162 POWER CONTROL UNIT, 163 ATTENUATOR, 164 AMPLIFIER, 165 AMPLIFIER, 166 MODE CONVERTER, 200 FIRST WAVE DETECTION UNIT, 202 DIODE, 203 CAPACITOR, 205 FIRST A/D CONVERTER, 206 FIRST PROCESSING UNIT, 207 STORAGE DEVICE, 210 SECOND WAVE DETECTION UNIT, 212 DIODE, 213 CAPACITOR, 215 SECOND A/D CONVERTER, 216 SECOND PROCESSING UNIT, 217 STORAGE DEVICE, 301 ATTENUATOR, 302 LOW-PASS FILTER, 303 MIXER, 304 LOCAL OSCILLATOR, 305 FREQUENCY SWEEPING CONTROLLER, 306 IF AMPLIFIER, 307 IF FILTER, 308 LOG AMPLIFIER, 309 DIODE, 310 CAPACITOR, 311 BUFFER AMPLIFIER, 312 A/D CONVERTER, 313 FIRST PROCESSING UNIT, 314 STORAGE DEVICE, 321 ATTENUATOR, 322 LOW-PASS FILTER, 323 MIXER, 324 LOCAL OSCILLATOR, 325 FREQUENCY SWEEPING CONTROLLER, 326 IF AMPLIFIER, 327 IF FILTER, 328 LOG AMPLIFIER, 329 DIODE, 330 CAPACITOR, 331 BUFFER AMPLIFIER, 332 A/D CONVERTER, 333 FIRST PROCESSING UNIT, 334 STORAGE DEVICE

1. A microwave output device comprising:
a microwave generation unit that generates a microwave having a frequency and a power respectively corresponding to a set frequency and a set power designated from a controller;
an output that outputs a microwave propagating from the microwave generation unit;
a first directional coupler that outputs a part of a travelling wave propagating toward the output from the microwave generation unit; and
a first measurement unit that determines a first measured value indicating a power of the travelling wave at the output on a basis of the part of the travelling wave output from the first directional coupler,
wherein the first measurement unit includes
a first wave detection unit that generates an analog signal corresponding to a power of the part of the travelling wave by using diode detection,
a first A/D converter that converts the analog signal generated by the first wave detection unit into a digital value, and
a first processing unit configured to select one or more first correction coefficients associated with the set frequency and the set power designated by the controller from among a plurality of first correction coefficients which are preset to correct the digital value generated by the first A/D converter to the power of the travelling wave at the output, and to determine the first measured value by multiplying the selected one or more first correction coefficients by the digital value generated by the first A/D converter.

2. The microwave output device according to claim 1,
wherein the plurality of first correction coefficients include a plurality of first coefficients respectively associated with a plurality of set frequencies and a plurality of second coefficients respectively associated with a plurality of set power levels, and
wherein the first processing unit is configured to determine the first measured value by multiplying a first coefficient and a second coefficient as the one or more first correction coefficients by the digital value generated by the first A/D converter, the first coefficient being one associated with the set frequency designated by the controller among the plurality of first correction coefficients and the second coefficient being one associated with the set power designated by the controller among the plurality of first correction coefficients.

3. The microwave output device according to claim 1, further comprising:
a second directional coupler that outputs a part of a reflected wave returning to the output; and
a second measurement unit that determines a second measured value indicating a power of the reflected wave at the output on a basis of the part of the reflected wave output from the second directional coupler,
wherein the second measurement unit includes
a second wave detection unit that generates an analog signal corresponding to a power of the part of the reflected wave by using diode detection,
a second A/D converter that converts the analog signal generated by the second wave detection unit into a digital value, and
a second processing unit configured to select one or more second correction coefficients associated with the set frequency and the set power designated by the controller from among a plurality of second correction coefficients which are preset to correct the digital value generated by the second A/D converter to the power of the reflected wave at the output, and to determine the second measured value by multiplying the selected one or more second correction coefficients by the digital value generated by the second A/D converter.

4. The microwave output device according to claim 3,
wherein the plurality of second correction coefficients include a plurality of third coefficients respectively associated with a plurality of set frequencies and a plurality of fourth coefficients respectively associated with a plurality of set power levels, and
wherein the second processing unit is configured to determine the second measured value by multiplying a third coefficient and a fourth coefficient as the one or more second correction coefficient by the digital value generated by the second A/D converter, the third coefficient being one associated with the set frequency designated by the controller among the plurality of third coefficients and the fourth coefficient being one associated with the set power designated by the controller among the plurality of fourth coefficients.

5. A microwave output device comprising:
a microwave generation unit that generates a microwave having a frequency and a power respectively corresponding to a set frequency and a set power designated from a controller;
an output that outputs a microwave propagating from the microwave generation unit;
a first directional coupler that outputs a part of a travelling wave propagating toward the output from the microwave generation unit; and
a first measurement unit that determines a first measured value indicating a power of the travelling wave at the output on a basis of the part of the travelling wave from the first directional coupler,
wherein the first measurement unit includes
a first spectrum analysis unit that obtains a digital value indicating a power of the part of the travelling wave, and
a first processing unit configured to select a first correction coefficient associated with the set frequency designated by the controller from among a plurality of first correction coefficients which are preset to correct the digital value obtained by the first spectrum analysis unit to the power of the travelling wave at the output, and to determine the first measured value by multiplying the selected first correction coefficient by the digital value obtained by the first spectrum analysis unit.

6. The microwave output device according to claim 5, further comprising:
a second directional coupler that outputs a part of a reflected wave returning to the output; and
a second measurement unit that determines a second measured value indicating a power of the reflected wave at the output on a basis of the part of the reflected wave output from the second directional coupler,
wherein the second measurement unit includes
a second spectrum analysis unit that obtains a digital value indicating a power of the part of the reflected wave, and
a second processing unit configured to select a second correction coefficient associated with the set frequency designated by the controller from among a plurality of second correction coefficients which are preset to correct the digital value obtained by the second spectrum analysis unit to the power of the reflected wave at the output, and to determine the second measured value by multiplying the selected second correction coefficient by the digital value obtained by the second spectrum analysis unit.

7. The microwave output device according to claim 3,
wherein the microwave generation unit includes a power control unit that adjusts a power of the microwave generated by the microwave generation unit to make a difference between the first measured value and the second measured value closer to the set power designated by the controller.

8. A plasma processing apparatus comprising:
a chamber body; and
the microwave output device according to claim 1 that outputs a microwave for exciting a gas to be supplied to the chamber body.

9. The microwave output device according to claim 6,
wherein the microwave generation unit includes a power control unit that adjusts a power of the microwave generated by the microwave generation unit to make a difference between the first measured value and the second measured value closer to the set power designated by the controller.

10. A plasma processing apparatus comprising:
a chamber body; and
the microwave output device according to claim 5 that outputs a microwave for exciting a gas to be supplied to the chamber body.
